(19) United States
(12) Patent Application Publication
(10) Pub. No.: US 2021/0296622 A1
(43) Pub. Date: Sep. 23, 2021

(54) LIGHT EMITTING FIBERS

(71) Applicants: The Regents of the University of California, Oakland, CA (US); William Marsh Rice University, Houston, TX (US)

(72) Inventors: Armand Paul Alivisatos, Berkeley, CA (US); Farnaz Niroui, Cambridge, MA (US); Vida Jamali, Menlo Park, CA (US); Matteo Pasquali, Houston, TX (US)

(21) Appl. No.: 17/265,510

(22) PCT Filed: Aug. 1, 2019
(86) PCT No.: PCT/US2019/044741

§ 371 Date: Feb. 2, 2021

Related U.S. Application Data
(60) Provisional application No. 62/714,561, filed on Aug. 3, 2018.

(51) Int. Cl. H01L 51/52; C01B 32/168; C09K 11/06; C09K 11/02; C09K 11/08; H01L 51/00; D01F 9/12; D01F 11/10; H01L 51/50; H01L 51/56; H05B 45/00

(52) U.S. Cl. CPC H01L 51/5287; B82Y 20/00; C09K 11/06; C09K 11/02; C09K 11/08; H01L 51/0049; H01L 51/0077; H01L 51/004; H01L 51/0037; H01L 51/0035; D01F 9/12; D01F 11/10; H01L 51/502; H01L 51/5032; H01L 51/5056; H01L 51/5072; H01L 51/5088; H01L 51/5092; H01L 51/5206; H01L 51/5253; H01L 51/0021; H01L 51/56; H05B 45/60; C01B 32/168

(57) ABSTRACT

In various embodiments a light emitting fiber is provided as well as articles of manufacture comprising one or more light emitting fibers. In certain embodiments the light emitting fiber comprises a conductive carbon nanotube fiber; an emissive layer surrounding the carbon nanotube fiber; and a conductive outer layer disposed outside the emissive layer. In certain embodiments the light emitting fiber comprises a hole transport layer disposed between the carbon nanotube fiber and the emissive layer. In certain embodiments the light emitting fiber comprise a hole injection layer disposed between the nanotube fiber and the hole transport layer. In certain embodiments the light emitting fiber comprises an electron transport layer and, optionally an electron injection layer.

### CROSS-REFERENCE TO RELATED APPLICATIONS

This application claims priority to and benefit of U.S. Ser. No. 62/714,561, filed on Aug. 3, 2018, which is incorporated herein by reference in its entirety for all purposes.

### STATEMENT OF GOVERNMENTAL SUPPORT

This invention was made with government support under Grant No. FA9550-15-1-0370 awarded by the Air Force Office of Scientific Research (AFOSR). The Government has certain rights in this invention.

### BACKGROUND

Fiber-like light emitting diodes find utility in a wide variety of contexts including, but not limited to small light sources (e.g., as individual fibers), in medical applications such as for optogenetics, in flexible displays including, but not limited to textile displays, and in numerous other articles of manufacture.

Among the applications for e-textiles, wearable displays have attracted considerable attention. Various strategies have been developed to realize wearable displays, including, for example, the use of ultrathin and/or stretchable electronic materials (see, e.g., White et al. (2013) Nat. Photonics, 7(10): 811-816; Choi et al. (2015) Nat. Commun. 6: 7149; Yokota et al. (2016) Sci. Adv. 2(4): e1501856-e1501856). In addition, methods of directly fabricating displays on textiles and/or fibers have been pursued by utilizing inorganic light-emitting diodes (LEDs) fabricated directly on textiles and/or fibers (see, e.g., Cherenack et al. (2010) Adv. Mater. 22(45): 5178-5182.; Hu et al. (2011) Adv. Funct. Mater. 21(2): 305-311), organic LEDs (OLEDs) (see, e.g., Kim et al. (2013) Org. Electron, 14(11): 3007-3013; Kim et al. (2016) Adv. Electron. Mater. 2(11): 1600220; Choi et al. (2017) Sci. Rep. 7(1): 6424; Lee et al. (2017) IEEE Trans. Electron Dev. 64(5): 1922-1931; Kim et al. (2015) J. Inf. Disp. 16(4): 179-184; Kwon et al. (2015) Adv. Electron. Mater. 1(9): 1500103; O'Connor et al. (2007) Adv. Mater. 19(22): 3897-3900; and the like) and polymer light-emitting electrochemical cells (PLECs) (see, e.g., Zhang et al. (2015) Nat. Photonics, 9: 233-238).

Among these strategies, fiber-based wearable display devices are considered to be highly desirable because they allow display functions to be incorporated without losing the inherent properties of hierarchically woven clothes, which include important characteristics such as flexibility, and comfort.

While various examples of light emitting fibers have been produced, these fibers mostly rely on using stainless steel or plastic fibers as the support material which suffer from low flexibility limiting their potential to be fully integrated with fabrics. Additionally, deposition of the functional layers on top of the supporting fiber typically requires high-vacuum deposition steps which are not scalable and versatile.

### SUMMARY

As described herein, in various embodiments, light-emitting fibers are provided through coaxially coating a wet-spun carbon nanotube fiber with materials needed to enable electrically pumped light emission. Carbon nanotube fibers allow for a flexible and yet an electrically conductive support material for our electrically pumped light emitting fibers. Moreover, our processing approach allows for a cheap, scalable and versatile method for fabricating light emitting fibers.

Various embodiments contemplated herein may include, but need not be limited to, one or more of the following:

Embodiment 1: A light emitting fiber, said fiber comprising:
a conductive carbon nanotube fiber;
an emissive layer surrounding said carbon nanotube fiber; and
a conductive outer layer disposed outside said emissive layer.

Embodiment 2: The light emitting fiber of embodiment 1, wherein said light emitting fiber comprises a hole transport layer disposed between said carbon nanotube fiber and said emissive layer.

Embodiment 3: The light emitting fiber of embodiments 2, wherein said light emitting fiber comprise a hole injection layer disposed between said nanotube fiber and said hole transport layer.

Embodiment 4: The light emitting fiber according to any one of embodiments 1-3, wherein said light emitting fiber comprises an electron transport layer disposed between said emissive layer and said conductive outer layer.

Embodiment 5: The light emitting fiber according to any one of embodiments 1-4, wherein said light emitting fiber comprises an electron injection layer disposed between said electron transport layer and said conductive outer layer.

Embodiment 6: The light emitting fiber of embodiment 1, wherein said light emitting fiber comprises a hole transport layer disposed between said emissive layer and said conductive outer layer.

Embodiment 7: The light emitting fiber of embodiment 6, wherein said light emitting fiber comprises a hole injection layer disposed between said hole transport layer and said conductive outer layer.

Embodiment 8: The light emitting fiber of embodiments 1 and 6-7, wherein said light emitting fiber comprises an electron transport layer disposed between said carbon nanotube fiber and said emissive layer.

Embodiment 9: The light emitting fiber of embodiment 8, wherein said light emitting fiber comprise an electron injection layer disposed between said carbon nanotube fiber and said electron transport layer.

Embodiment 10: The light emitting fiber according to any one of embodiments 1-9, wherein said carbon nanotube fiber comprise a single carbon nanotube fiber (CNTf).

Embodiment 11: The light emitting fiber according to any one of embodiments 1-9, wherein said carbon nanotube fiber comprise a plurality of carbon nanotube fibers.

Embodiment 12: The light emitting fiber according to any one of embodiments 1-11, wherein said carbon nanotube fibers are p-doped.

Embodiment 13: The light emitting fiber according to any one of embodiments 1-12, wherein said carbon nanotube fiber(s) range in diameter from about 1 μm, or from about 5 μm, or from about 10 μm, or from about 15 μm up to about 100 μm, or up to about 50 μm, or up to about 40 μm, or up to about 35 μm.

Embodiment 14: The light emitting fiber of embodiment 13, wherein said carbon nanotube fiber (s) range in diameter from about 15 μm up to about 35 μm.

Embodiment 15: The light emitting fiber according to any one of embodiments 1-14, wherein said carbon nanotube fiber(s) have a specific electrical conductivity at 20° C. higher than about 0.6×10⁴ S*cm²/g, or higher than about 2×10⁴ S*cm²/g, or higher than about 1.3×10⁵ S*cm²/g.

Embodiment 16: The light emitting fiber according to any one of embodiments 1-15, wherein said carbon nanotube fiber(s) have a current-carrying capacity of at least about 2000 A/cm, or at least about 10000 A/cm, or at least about 20000 A/cm, or at least about 30000 A/cm, a CNT fiber 25 μm in diameter.

Embodiment 17: The light emitting fiber according to any one of embodiments 1-16, wherein said nanotube fiber(s) have a modulus of at least about 120 GPa, or at least about 150 GPa, or at least about 200 GPa.

Embodiment 18: The light emitting fiber according to any one of embodiments 1-17, wherein said emissive layer comprises an inorganic nanoparticle layer, an inorganic thin film layer, an organic molecule emissive layer, or a polymeric emissive layer.

Embodiment 19: The light emitting fiber of embodiment 18, wherein said emissive layer comprises an inorganic nanoparticle layer and/or an inorganic thin film layer.

Embodiment 20: The light emitting fiber of embodiment 19, wherein said emissive layer comprises a metal halide perovskite.

Embodiment 21: The light emitting fiber of embodiment 20, wherein the metal halide perovskite comprises a material according to the formula CH₃NH₃MX, where M is Pb or SN, and X is one or two halides.

Embodiment 22: The light emitting fiber of embodiment 21, wherein said emissive layer comprises a lead halide perovskite.

Embodiment 23: The light emitting fiber of embodiment 22, wherein said emissive layer comprises a compound selected from the group consisting of CH₃NH₃PbBr₃, CH₃NH₃PbCl₃, CH₃NH₃PbI₃.

Embodiment 24: The light emitting fiber of embodiment 22, wherein said emissive layer comprises a CH₃NH₃PbBr₃.

Embodiment 25: The light emitting fiber of embodiment 21, wherein said emissive layer comprise a perovskite selected from the group consisting of CH₃NH₃PbI₃, CH₃NH₃,PbBr₃, CH₃NH₃PbCl₃, CH₃NH₃PbF₃, CH₃NH₃PbBrI₂, CH3NH3PbBrCl2, CH3NH3PbIBr2, CH₃NH₃PbICl₂, CH₃NH₃PbClBr₂, CH₃NH₃PbI₂Cl, CH₃NH₃SnI₃, CH₃NH₃SnBr₃, CH₃NH₃SnCl₃, CH₃NH₃ SnF₃, CH₃NH₃SnBrI₂, CH₃NH₃SnBrCl₂, CH₃NH₃SnF₂Br, CH₃NH₃SnIBr₂, CH₃,NH₃SnICl₂, CH₃NH₃SnF₂I, CH₃NH₃SnClBr₂, CH₃NH₃SnI₂Cl, and CH₃NH₃SnF₂Cl.

Embodiment 26: The light emitting fiber according to any one of embodiments 22-25, wherein said emissive layer comprises perovskite nanocrystals/nanoparticles embedded in a polymer matrix.

Embodiment 27: The light emitting fiber of embodiment 26, wherein said wherein said polymer matrix comprises a polymer selected from the group consisting of PVP, and PEO.

Embodiment 28: The light emitting fiber of embodiment 19, wherein said inorganic nanoparticle layer or inorganic thin film layer comprises a material selected from the group consisting of Aluminium gallium arsenide (AlGaAs), Aluminium gallium indium nitride (AlGaInN), Aluminium gallium indium phosphide (AlGaInP), Aluminium gallium nitride (AlGaN), Aluminium gallium phosphide (AlGaP), Aluminium nitride (AlN), Boron nitride, Gallium arsenide (GaAs), Gallium arsenide phosphide (GaAsP), Gallium arsenide phosphide (GaAsP), Gallium arsenide phosphide (GaAsP), Gallium(III) nitride (GaN), Gallium(III) phosphide (GaP), Gallium(III) phosphide (GaP), Gallium(III) phosphide (GaP), Gallium(III) phosphide (GaP), Indium gallium nitride (InGaN), Indium gallium nitride (InGaN), Indium gallium nitride (InGaN), Indium gallium nitride (InGaN) (385-400 nm), and Zinc selenide (ZnSe).

Embodiment 29: The light emitting fiber of embodiment 18, wherein said emissive layer comprises an organic molecule emissive layer, and/or a polymeric emissive layer.

Embodiment 30: The light emitting fiber of embodiment wherein the emissive layer comprises a conjugated polymer.

Embodiment 31: The light emitting fiber of embodiment 30, wherein the emissive layer comprise a compound selected from the group consisting of Alq3 (tris(8-hydroxyquinolinato)aluminium), a polyphenylene or derivative thereof, a polyfluorenes or derivative thereof, a polythiophene or derivative thereof, polyfluoroene (PF), a polyphenylene vinylene (e.g., polyphenylene PPP) and derivatives thereif (e.g., poly[{2,5-di(3′,7′-dimethyloctyloxy)-1,4-phenylene-vinylene}-co-{3-(4′-(3″,7″-dimethyloctyloxy)phenyl)-1,4-phenylenevinylene}-co-{3-(3′-(3′,7′-dimethyloctyloxy)phenyl)-1,4-phenylenevinylene}] (aka. Super yellow or SY-PPV)), polyvinyl carbazole, and a polymers containing heteroaromatic rings.

Embodiment 32: The light emitting fiber of embodiment 30, wherein the emissive layer comprises a material selected from the group consisting of poly(p-phenylenevinylene) (PPV), polyphenylene (PPP), polyvinyl carbazole, Alq3, and super yellow.

Embodiment 33: The light emitting fiber of embodiment 30, wherein the emissive layer comprises a material selected from the group consisting of epidolidione, 1,1-bis(4-di-p-tolylaminophenyl)cyclohexane, [4,4′-bis[5,7-di(2-methyl-2-butyl)-2-benzoxazolyl]stilbene], [2,5-bis[5,7-di(2-methyl-2-butyl)-2-benzoxazolyl]thiophene], [2,2′-(1,4-phenylenedivinylene)bisbenzothiazole], [2,2′-(4,4′-biphenylene)bisbenzothiazole], [2,5-bis[5-(α,α-dimethylbenzyl)-2-benzoxazolyl]thiophene], [2,5-bis[5,7-di(2-methyl-2-butyl)-2-benzoxazolyl]-3,4-diphenyl-thiophene], and poly[2-methoxy-5-(2-ethylhexyloxy)-1,4-phenylenevinylene].

Embodiment 34: The light emitting fiber of embodiment 30, wherein the emissive layer comprises an Ir complex.

Embodiment 35: The light emitting fiber of embodiment 34, wherein the emissive layer comprises an Ir complex selected from the group consisting of to, ppy, tpy, zq, thp, dpo. C6, bo, bon, bt, op, αbsn, βbsn, tth, pq, and btp.

Embodiment 36: The light emitting fiber according to any one of embodiments 18-35, wherein said emissive layer ranges in thickness from about 10 nm, or from about 20 nm, or from about 30 nm, or from about 40 nm, or from about 50 nm up to about 500 nm, or up to about 400 nm, or up to about 300 nm, or up to about 200 nm, or up to about 100 nm, or up to about 500 nm, or up to about 1 μm, or up to about 5 μm, or up to about 10 μm, or up to about 20 μm, or up to about 30 μm, or up to about 40 μm, or up to about 50 μm.

Embodiment 37: The light emitting fiber according to any one of embodiments 2-36, wherein said hole transport layer, when present, comprises an organic molecule or polymer, or an inorganic nanoparticle or inorganic thin film.

Embodiment 38: The light emitting fiber of embodiment 37, wherein said hole transport layer comprises a layer or inorganic nanoparticles and/or an inorganic thin film.

Embodiment 39: The light emitting fiber of embodiment 38, wherein said inorganic nanoparticle and/or inorganic thin film comprises a materials selected from the group consisting of ZnO, TiO₂, CuI, and NiO.

Embodiment 40: The light emitting fiber of embodiment 37, wherein said hole transport layer comprises an organic molecule or polymer.

Embodiment 41: The light emitting fiber of embodiment 40, wherein said hole transport layer comprises a material selected from the group consisting of poly(3,4-ethylenedioxythiophene) polystyrene sulfonate (PDOT:PSS), poly(9-vinylcarbazole) (PVK), polybutadiene (PBD), poly(3-hexylthiophene), and 2,2′,7,7′-Tetrakis(N,N-di-p-methoxyphenylamine)-9,9′-spirobifluorene.

Embodiment 42: The light emitting fiber of embodiment 41, wherein said hole transport layer comprises poly(3,4-ethylenedioxythiophene) polystyrene sulfonate (PDOT:PSS).

Embodiment 43: The light emitting fiber of embodiment 40, wherein said hole transport layer comprises a material selected from the group consisting of a starburst triamine, a CFx fluorohydrocarbon polymer, a triarylamine or polythiophene polymer with conductivity dopants, an arylamine complexed a metal oxides, a p-type semiconducting organic complex, a triarylamine, a triaylamine on a spirofluorene core, an arylamine carbazole compound, a triarylamine with (di)benzothiophene/, (di)benzofuran, indolocarbazoles, an isoindole compound, and a metal carbene complex.

Embodiment 44: The light emitting fiber of embodiment 43, wherein said hole transport layer comprises a material shown in Table 2.

Embodiment 45: The light emitting fiber according to any one of embodiments 37-44, wherein said hole transport layer ranges in thickness from about 10 nm, or from about 20 nm, or from about 30 nm, or from about 40 nm, or from about 50 nm up to about 500 nm, or up to about 400 nm, or up to about 300 nm, or up to about 200 nm, or up to about 100 nm, or up to about 500 nm, or up to about 1 μm, or up to about 5 μm, or up to about 10 μm, or up to about 20 μm, or up to about 30 μm, or up to about 40 μm, or up to about 50 μm.

Embodiment 46: The light emitting fiber according to any one of embodiments 3-45, wherein said hole injection layer, when present, comprises a material shown in Table 3.

Embodiment 47: The light emitting fiber of embodiment 46, wherein said hole transport layer ranges in thickness from about 10 nm, or from about 20 nm, or from about 30 nm, or from about 40 nm, or from about 50 nm up to about 500 nm, or up to about 400 nm, or up to about 300 nm, or up to about 200 nm, or up to about 100 nm, or up to about 500 nm, or up to about 1 μm, or up to about 5 μm, or up to about 10 μm, or up to about 20 μm, or up to about 30 μm, or up to about 40 μm, or up to about 50 μm.

Embodiment 48: The light emitting fiber according to any one of embodiments 4-47, wherein said electron transport layer comprises an inorganic nanoparticle or inorganic thin film, or an organic molecule or polymer.

Embodiment 49: The light emitting fiber of embodiment 48, wherein said electron transport layer comprises a layer or inorganic nanoparticles and/or an inorganic thin film.

Embodiment 50: The light emitting fiber of embodiment 49, wherein said inorganic nanoparticle and/or inorganic thin film comprises a materials selected from the group consisting of ZnO, TiO₂, CuI, and NiO.

Embodiment 51: The light emitting fiber of embodiment 50, wherein said inorganic nanoparticles and/or inorganic thin film comprises ZnO.

Embodiment 52: The light emitting fiber of embodiment 48, wherein said electron transport layer comprises a organic molecule or polymer.

Embodiment 53: The light emitting fiber according to any one of embodiments 48-52, wherein said electron transport layer ranges in thickness from about from about 10 nm, or from about 20 nm, or from about 30 nm, or from about 40 nm, or from about 50 nm up to about 500 nm, or up to about 400 nm, or up to about 300 nm, or up to about 200 nm, or up to about 100 nm, or up to about 500 nm, or up to about 1 μm, or up to about 5 μm, or up to about 10 μm, or up to about 20 μm, or up to about 30 μm, or up to about 40 μm, or up to about 50 μm.

Embodiment 54: The light emitting fiber according to any one of embodiments 5-53, wherein said electron injection layer comprises a material selected from the group consisting of (ZnO), 2-(2,4,6-Trimethoxyphenyl)-1,3-dimethyl-1H-benzoimidazol-3-ium (R3), (2-(2-methoxyphenyl)-1,3-dimethyl-1H-benzoimidazol-3-ium (o-MeO-DMBI or R1), LiF, and PETE.

Embodiment 55: The light emitting fiber of embodiment 54, wherein said electron injection layer, when present, ranges in thickness from about 10 nm, or from about 20 nm, or from about 30 nm, or from about 40 nm, or from about 50 nm up to about 500 nm, or up to about 400 nm, or up to about 300 nm, or up to about 200 nm, or up to about 100 nm, or up to about 500 nm, or up to about 1 μm, or up to about 5 μm, or up to about 10 μm, or up to about 20 μm, or up to about 30 μm, or up to about 40 μm, or up to about 50 μm.

Embodiment 56: The light emitting fiber according to any one of embodiment 1-55, wherein said conductive outer layer comprises a material selected from the group consisting of metallic or doped semiconducting nanoparticles, inorganic thin films, organic molecules and/or polymer layers.

Embodiment 57: The light emitting fiber of embodiment 56, wherein the conductive outer layer comprises a material selected from the group consisting of silver nanowires, gold nanowires, carbon nanotubes, graphene, indium zinc oxide (IZO, indium tin oxide (ITO), and PDOT:PSS.

Embodiment 58: The light emitting fiber of embodiment 56, wherein the conductive outer layer comprises silver.

Embodiment 59: The light emitting fiber according to any one of embodiments 56-58, wherein said electron transport layer ranges in thickness from about 10 nm, or from about 20 nm, or from about 30 nm, or from about 40 nm, or from about 50 nm up to about 500 nm, or up to about 400 nm, or up to about 300 nm, or up to about 200 nm, or up to about 100 nm, or up to about 500 nm, or up to about 1 μm, or up to about 5 μm, or up to about 10 μm, or up to about 20 μm, or up to about 30 μm, or up to about 40 μm, or up to about 50 μm.

Embodiment 60: The light emitting fiber according to any one of embodiments 1-59, wherein said emissive layer is substantially continuous along the length of said fiber.

Embodiment 61: The light emitting fiber according to any one of embodiments 1-59, wherein said emissive layer is disposed in one or more discrete locations along the length of said fiber.

Embodiment 62: The light emitting fiber according to any one of embodiments 1-61, wherein said emissive layer composition is substantially constant along the length of said fiber.

Embodiment 63: The light emitting fiber according to any one of embodiments 1-61, wherein said emissive layer composition varies in composition with location along the length of said fiber.

Embodiment 64: The light emitting fiber according to any one of embodiments 1-63, wherein said fiber is coated with an encapsulating material to reduce or prevent environmental degradation.

Embodiment 65: The light emitting fiber of embodiment 64, wherein said encapsulating material comprises a polymer.

Embodiment 66: The light emitting fiber of embodiment 65, wherein said encapsulating material comprises a material selected from the group consisting of (poly(methylmethacrylate) (PMMA), ethyl cellulose, polycarbonate and poly(4-methyl-1-pentene)), parylene, and epoxy.

Embodiment 67: The light emitting fiber according to any one of embodiments 1-66, where a plurality of said light emitting fibers are braided together to form a bundle.

Embodiment 68: The light emitting fiber according to any one of embodiments 1-66, where a plurality of said light emitting fibers are twisted together to form a bundle.

Embodiment 69: The light emitting fiber according to any one of embodiments 67-68, wherein said bundle comprises fibers that emit at different wavelengths.

Embodiment 70: The light emitting fiber according to any one of embodiments 1-69, wherein said light emitting fiber or a bundle of light emitting fibers is weavable.

Embodiment 71: The light emitting fiber of embodiment 70, wherein said light emitting fiber(s) are a component of a textile.

Embodiment 72: The light emitting fiber of embodiment 71, wherein said light emitting fiber is a component of a textile comprising other light emitting fibers.

Embodiment 73: The light emitting fiber according to any one of embodiments 71-72, wherein said light emitting fiber is a component of a textile comprising additional electronic components.

Embodiment 74: A method for producing light emission from a light emitting fiber, said method comprising:
providing a light emitting fiber according to any one of embodiments 1-73; and
applying a voltage between the carbon nanotube fiber(s) and the conductive layer sufficient to produce light emission from said light emitting fiber(s).

Embodiment 75: The method of embodiment 74, wherein said voltage ranges from about 0.1 V, or about 0.5 V, or about 1 V up to about 50 V, or up to about 40 V, or up to about 30 V, or up to about 20 V, or up to about 10 V, or up to about 9 V, or up to about 5 V.

Embodiment 76: An article of manufacture comprising a light emitting fiber according to any one of embodiments 1-73.

Embodiment 77: The article of manufacture of embodiment 76, wherein said article of manufacture comprises a textile.

Embodiment 78: The article of manufacture according to any one of embodiments 76-77, wherein said light emitting fiber provides a source of illumination.

Embodiment 79: The article of manufacture according to any one of embodiments 76-77, wherein said light emitting fiber provides component of a display that produces an image and/or an alphanumeric character.

Embodiment 80: A method of fabricating a light emitting fiber, said method comprising:
providing a carbon nanotube fiber;
coating said carbon nanotube fiber with an emissive layer to form a coated nanotube fiber structure; and
coating said structure with a layer that forms a conductive layer disposed outside said emissive layer.

Embodiment 81: The method of embodiment 80, wherein said method comprises coating said nanotube fiber with a hole transport layer disposed before coating said nanotube fiber with said emissive layer.

Embodiment 82: The method of embodiment 81, wherein said method comprises coating said nanotube fiber with a hole injection layer before coating said nanotube fiber with said hole transport layer.

Embodiment 83: The method according to any one of embodiments 80-82, wherein said method comprises coating said nanotube fiber structure with an electron transport layer before coating said structure with the layer that forms a conductive layer.

Embodiment 84: The method according to any one of embodiments 80-83, wherein said providing a carbon nanotube fiber comprises using wet-spinning to produce said carbon nanotube fiber.

Embodiment 85: The method of embodiment 84, wherein said wet spinning comprises:
supplying a spin-dope comprising carbon nanotubes (CNT) to a spinneret;
extruding the spin-dope through at least one spinning hole in the spinneret to form spun CNT fiber(s); and
coagulating the spun CNT fiber(s) in a coagulation medium (a non-solvent) to form a solid CNT fiber.

Embodiment 86: The method of embodiment 85, wherein said spin-dope comprises a carbon nanotubes in a super acid solution.

Embodiment 87: The method of embodiment 86, wherein said super acid solution comprises chlorosulfonic acid.

Embodiment 88: The method according to any one of embodiments 80-87, wherein said carbon nanotube fiber is doped.

Embodiment 89: The method according to any one of embodiments 80-88, wherein the coating steps is through a roll-to-roll liquid-phase processing technique.

Embodiment 90: The method of embodiment 89, wherein said roll-to-roll processing techniques comprises holding the fiber under tension using at least two winding drums rotating at the same speed but in different directions and passing the fiber through a solution of the desired material to be coated.

Embodiment 91: The method of embodiment 90, wherein extra drums provided to guide the fiber and ensure an appropriate receding angle at the coating stage.

Embodiment 92: The method according to any one of embodiments 90-91, wherein a motorized roller is used to determine the speed at which the fiber moves through the solution is controlled to tune the coating thickness achieved.

Embodiment 93: The method according to any one of embodiments 80-92, wherein the thickness of each of the coatings varies between tens to thousands or between tens to hundreds of nanometers or even up to a micron.

Embodiment 94: The method according to any one of embodiments 90-93, wherein a single coating pass is used for each layer.

Embodiment 95: The method according to any one of embodiments 90-93, wherein multiple passes are used for one or more layers.

Embodiment 96: The method according to any one of embodiments 80-95, where a furnace is used to anneal a coating at the appropriate temperature as needed.

Embodiment 97: The method according to any one of embodiments 80-96, wherein the entire coating process takes place in an inert environment.

Embodiment 98: The method according to any one of embodiments 80-96, wherein the entire coating process takes place in air.

Embodiment 99: The method of embodiment 98, wherein said inert environment comprises nitrogen or argon.

Embodiment 100: The method according to any one of embodiments 80-99, wherein said method produces a light emitting fiber according to any one of embodiments 1-66.

### Definitions

The term “emissive layer material” refers to a material that emits light in response to an applied voltage/current.

An “emissive layer” refers to a layer formed on a substrate where the layer comprises one or more emissive layer materials. In various embodiments the emissive layer can be composed of a single layer of emissive material, multiple layers, or layers formed from composite of different types of material where each component can be emissive or only one component is emissive mixed in a support matrix (for example a nanoparticle-polymer composite layer). In certain embodiments the emissive layer comprises micro/nano crystals in a polymer composite.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

The term “perovskite”, as used herein, refers to a material with a crystal structure related to that of CaTiO₃ or a material comprising a layer of material, which layer has a structure related to that of CaTiO₃. In various embodiments the perovskite films and nanoparticles thereof that are currently used in the devices for the emissive layer(s) are not of the same type as CaTiO₃ (CaTiO₃ is insulating), but have the general crystal structure. The structure of CaTiO₃ can be represented by the formula ABX₃, wherein A and B are cations of different sizes and X is an anion. In the unit cell, the A cations are at (0,0,0), the B cations are at (½, ½, ½) and the X anions are at (½, ½, 0). The A cation is usually larger than the B cation. The skilled person will appreciate that when A, B and X are varied, the different ion sizes may cause the structure of the perovskite material to distort away from the structure adopted by CaTiO₃ to a lower-symmetry distorted structure. The symmetry will also be lower if the material comprises a layer that has a structure related to that of CaTiO₃. Materials comprising a layer of perovskite material are well known. For instance, the structure of materials adopting the K₂NiF4-type structure comprises a layer of perovskite material. The skilled person will appreciate that, in certain embodiments, a perovskite material can be represented by the formula [A][B][X]₃, where [A] is at least one cation, [B] is at least one cation and [X] is at least one anion. When the perovskite comprises more than one A cation, the different A cations may distributed over the A sites in an ordered or disordered way. When the perovskite comprises more than one B cation, the different B cations may distributed over the B sites in an ordered or disordered way. When the perovskite comprises more than one X anion, the different X anions may distributed over the X sites in an ordered or disordered way. The symmetry of a perovskite comprising more than one A cation, more than one B cation or more than one X cation, will be lower than that of CaTiO₃.

The term “metal halide perovskite”, as used herein, refers to a perovskite, the formula of which contains at least one metal cation and at least one halide anion. The term “organic-inorganic metal halide perovskite”, as used herein, refers to a metal halide perovskite, the formula of which contains at least one organic cation.

By “conjugated polymer” is meant a polymer which possesses a delocalized π-electron system along the polymer backbone; said delocalized π-electron system conferring semiconducting properties on the polymer and giving it the ability to transport positive and negative charge carriers with high mobilities along the polymer chain (see, e.g., Friend (1988) J. Mol. Electr. 4(1): 37-46).

The term “carbon nanotube fiber” is to be understood to include the final product and any intermediate of carbon nanotubes. For example, it encompasses the liquid stream of spin-dope spun out of a spinneret, the partly and fully coagulated fibers as present in the coagulation medium, the drawn fibers, and it encompasses also stripped, neutralized, washed and/or heat treated final fiber product.

The term fiber is to be understood to include filaments, yarns, ribbons and tapes. A fiber may have any desired length ranging from a millimeter to virtually endless. In certain embodiments, the fiber has a length of at least 10 cm, or at least 1 m, or at least 10 m, or at least 1000 m.

Carbon nanotube fibers having low resistivity have a high electrical conductivity. Conductivity is to be understood to mean the inverse of the resistivity. Carbon nanotube fibers may also exhibit a high thermal conductivity.

### BRIEF DESCRIPTION OF THE DRAWINGS

FIG. 1, panels A-C, schematically illustrates various embodiments of a light emitting fiber 100 comprising a carbon nanotube fiber 110, an emissive layer 130, and an outer conductor 150 (conductive layer) (see, panel A). Panel B: In certain embodiments the light emitting fiber can optionally additionally include a hole transport layer 120 disposed between the carbon nanotube fiber 110 and the emissive layer 130, and/or an electron transport layer 140 disposed between the outer conductor 150 and the emissive layer. In certain embodiments a hole injection layer 160 can optionally be disposed between hole transport layer 120 and the nanotube fiber 110. In certain embodiments an electron injection layer 180 can optionally be disposed between the outer conductor 150 and the electron transport layer 140. In certain embodiments the fiber can be encapsulated by a protective and typically transparent protective layer 170. Panel C: In certain embodiments the light emitting fiber can optionally additionally include a hole transport layer 120 disposed between the outer conductor 150 and the emissive layer 130, and/or an electron transport layer 140 disposed between the carbon nanotube fiber 110 and the emissive layer 130. In certain embodiments a hole injection layer 160 can optionally be disposed between hole transport layer 120 and the outer conductor 150. In certain embodiments an electron injection layer 180 can optionally be disposed between the carbon nanotube fiber 110 and the electron transport layer 140. In certain embodiments the fiber can be encapsulated by a protective and typically transparent protective layer 170.

FIG. 2 show a carbon nanotube fiber (left) that can be used in the light emitting fibers described herein as well as various illustrative functional layers (right) that can be deposited on the carbon nanotube to produce a light emitting fiber 100.

FIG. 3, panels A-G, illustrates one embodiment of a light emitting fiber. Panel A) Schematic showing the three-layered structure of a light emitting fiber. The CNT fiber is used as the bottom electrode, a PEO-perovskite layer is used as the emissive layer and a thin film of solver nanowire is used as the top electrode. Panel B) Photograph of a light emitting fiber. Panel C) Scanning electron microscopy of a three-layered light emitting fiber. Panel D) Scanning electron microscopy showing a CNT fiber before and after coating with the emissive layer and the top electrode. Panel E) Elemental analysis showing carbon (C) representing carbon nanotube, lead (Pb) representing PEO-perovskite emissive layer and silver (Ag) showing the silver nanowire top electrode. Panel F) Photoluminescence and electroluminescence of a light emitting fiber emitting in green. Panel G) Current density vs. voltage of a three-layered light emitting fiber in three tests.

FIG. 4, panels A & B, schematically illustrates two embodiments of a roll-to-roll coating set up to produce light emitting fibers. Panel A) An illustrative, but non-limiting coating method where a droplet of coating solution is drawn along the fiber. Panel B) An illustrative, but non-limiting coating method where the fiber is drawn through the coating solution. It will be recognized, however, that that other techniques including, but not limited to dip-coating, spray-coating, electrodeposition, electroplating, high-vacuum deposition techniques such as sputtering and evaporation, spinning and printing can also be used individually or in combination to coat the fibers.

### DETAILED DESCRIPTION

In various embodiments, light-emitting fibers are provided through coaxially coating a wet-spun carbon nanotube fiber with materials needed to enable electrically pumped light emission. Carbon nanotube fibers allow for a flexible and yet an electrically conductive support material for the electrically pumped light emitting fibers. Moreover, the approach described herein allows for a cheap, scalable and versatile method for fabricating light emitting fibers.

In this design, the carbon nanotube fiber characterized by high electrical conductivity and tunable doping characteristics serves as one of the electrodes used for charge injection. Additionally, it provides a structural support to receive the subsequent materials through a layer-by-layer scalable coating process leading to an overall flexible light emitting fiber with unprecedented mechanical properties. The flexibility of the fibers and the scalability of the fabrication process enables high throughput formation of these light-emitting structures that can further be braided or twisted into bundles and/or woven into large area fabrics.

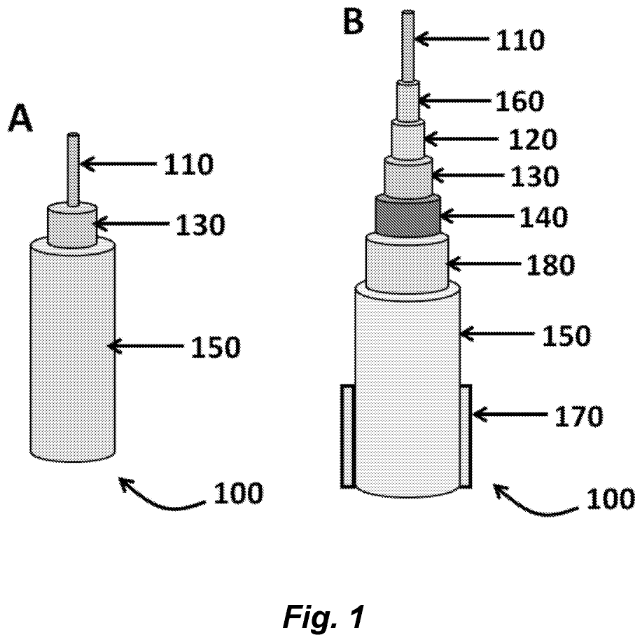

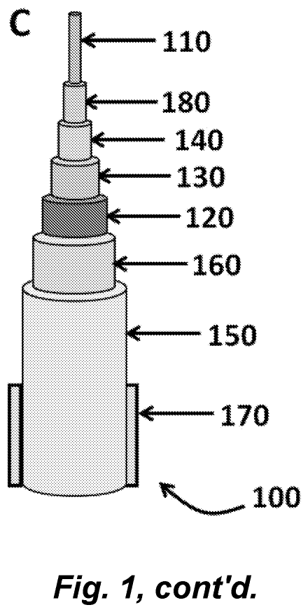

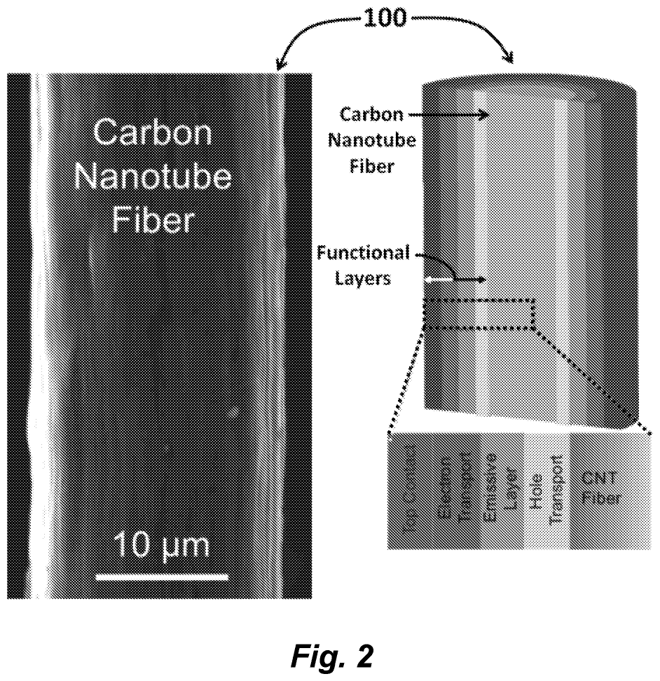

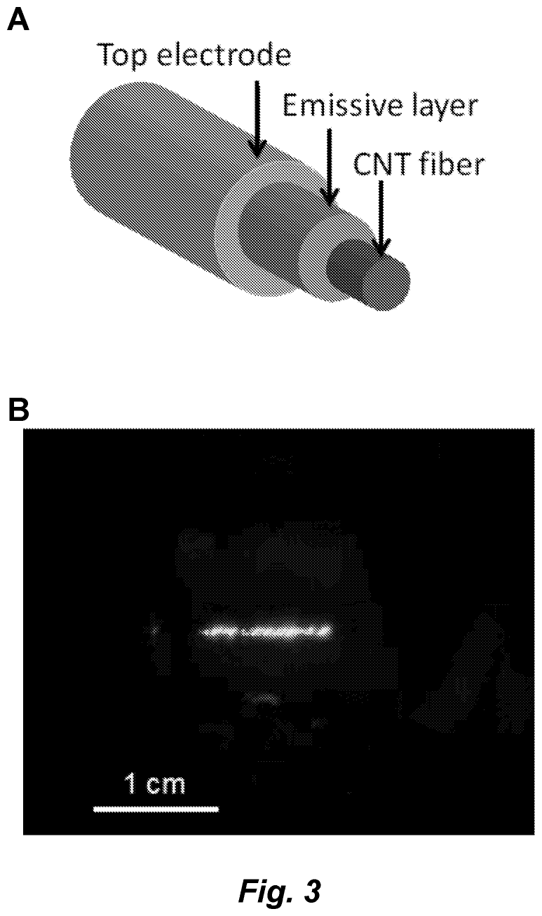

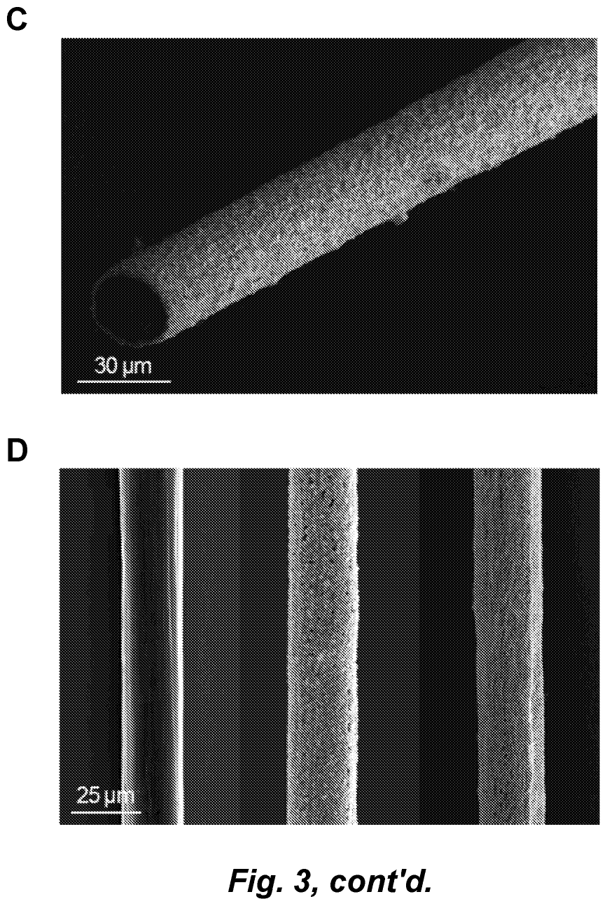

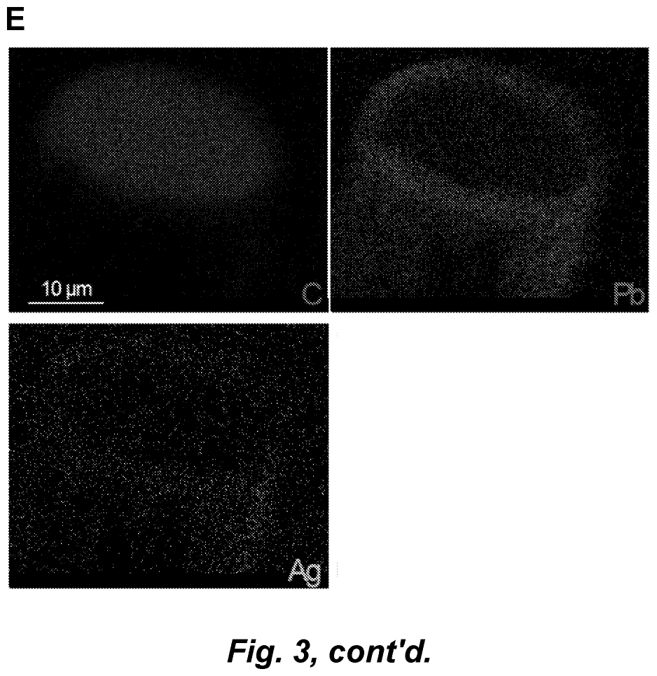

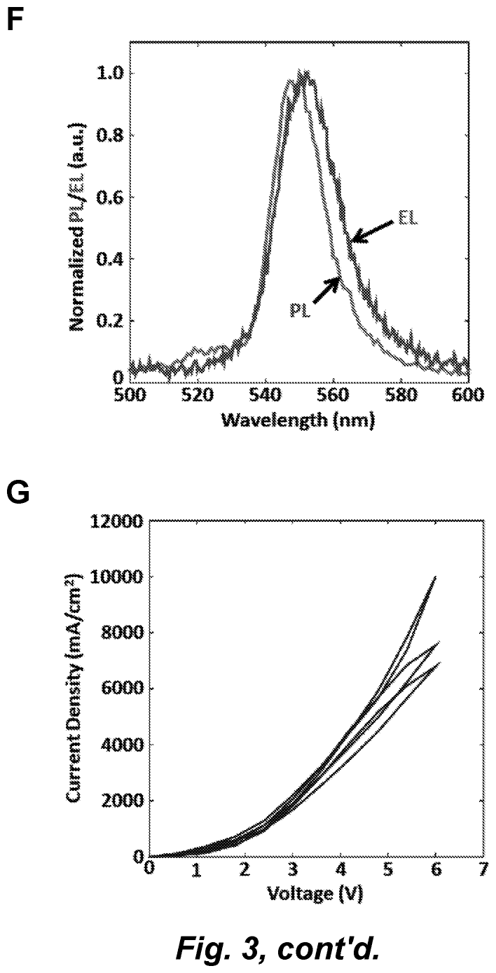

The structure of certain illustrative, but non-limiting, embodiments of the light emitting fibers are shown in FIGS. 1-3. In its simplest form the light emitting fiber 100 is comprised of three layers (see, FIG. 1, panel A): 1) a carbon nanotube fiber 110; 2) An emissive layer 130; and 3) a conductive outer layer 150 (top electrode). In various embodiments the emissive layer can consist of:
1) An organic molecular or polymer layer such as poly(phenylenevinylene) (PPV), polyfluorene (PF), polyphenylene (PPP), polyvinyl carbazole, Alq3, super yellow, and other materials, e.g., as described herein; and/or
2) Inorganic nanoparticles formed into a layer such as lead halide perovskite nanoparticles, metal chalcogenides, etc., e.g., as described herein; and/or
3) Inorganic thin films formed, e.g., through annealing of precursor solutions on the fiber or deposition through evaporation on the fiber such as lead halide perovskites, etc., e.g., as described herein; and/or
4) Organic-inorganic nanomaterial thin films or nanoparticles. In certain embodiments the organic-inorganic structure comprise a composite comprising an organic a support matrix (which may be emissive or non-emissive) incorporating emissive nanoparticles/crystals. In certain embodiments the organic-inorganic nanomaterial comprises perovskite nanomaterials/crystals imbedded in a polymer matrix.

However, to achieve greater efficiency, the light emitting fibers can optimally comprise one or more additional layers such as: 1) A hole transport layer 120; and/or 2) An electron transport layer 140; and/or 3) A hole injection layer 160; and/or 4) an electron injection layer 180; and/or 5) A protective encapsulating layer 170.

In certain embodiments, e.g., where the carbon nanotube fiber 110 functions as an anode (see, e.g., FIG. 1, panel B), the hole transport layer 120, when present, can be disposed between the carbon nanotube fiber 110 and the emissive layer 130. In certain embodiments, where a hole injection layer 160 is present the hole injection layer 160 can be disposed between the carbon nanotube fiber 110 and the hole transport layer 120. In certain embodiments, where an electron transport layer 140 is present, the electron transport layer 140 can be disposed between the outer electrode 150 and the emissive layer 130. In certain embodiments, where an electron injection layer 180 is present, the electron injection layer 180 can be disposed between the outer electrode 150 and the electron transport layer 140.

In certain embodiments, e.g., where the carbon nanotube fiber 110 functions as a cathode (see, e.g., FIG. 1, panel C), the hole transport layer 120, when present, can be disposed between the outer conductor 150 and the emissive layer 130. In certain embodiments, where a hole injection layer 160 is present the hole injection layer 160 can be disposed between the outer conductor 150 and the hole transport layer 120. In certain embodiments, where an electron transport layer 140 is present, the electron transport layer 140 can be disposed between the carbon nanotube fiber 110 and the emissive layer 130. In certain embodiments, where an electron injection layer 180 is present, the electron injection layer 180 can be disposed between the carbon nanotube fiber 110 and the electron transport layer 140.

In certain embodiments the hole transport layer(s) 120 and/or electron transport layer(s) 140, and/or the hole injection layer(s) 160, and/or the electrode injection layer(s) 180 can comprise:
1. Organic molecules or polymer such as TPBi, bathocuproine (BCP), Poly(9-vinylcarbazole) (PVK), polybutadiene (PBD), PEDOT:PSS, P3HT, spiro-OMeTAD; and the like, e.g., as described herein; and/or
2. Inorganic nanocrystals such as ZnO, TiO₂, CuI, NiO, and the like, e.g., as described herein; and/or
3. Inorganic thin films formed, e.g., by annealing a precursor solution on the fiber such as ZnO, and the like, e.g., as described herein.

In certain illustrative but non-limiting embodiments the top electrode in these fibers can be formed of metallic or doped semiconducting nanoparticles, inorganic thin-films or polymeric layers. Examples include an interconnected mesh of silver nanowires, gold nanowires, carbon nanotube, graphene, PEDOT:PSS, etc., e.g., as described herein. In certain embodiments particle-polymer composite layers can also be used.

In certain embodiments light emitting fibers in which each characteristic layer consists of a mixture of different materials or graded layers formed from different materials are also possible.

In certain embodiments the light emitting fibers are produced by providing wet-spun carbon nanotube fibers that are coaxially coated with various nanomaterials including, for example hole transfer, emissive, and electron transfer layers in consecutive steps. The coating can be done in solution phase, however, large area vacuum deposition techniques can also be implemented. Depending on the material(s) used the coating step may need to be followed by an annealing or surface functionalization step. In certain embodiments surface functionalizing also can be done prior to applying the coating to ensure uniform coating of the layer by changing the surface wetting properties.

The process outlined above provides an example of all-solution processable fabrication scheme for the proposed light emitting fibers. Suitable fabrication techniques however are not limited to this process. Beyond the roll-to-roll technique described above, other coating processes including dip-coating, spray-coating, electrodeposition, electroplating, high-vacuum deposition techniques such as sputtering and evaporation, spinning and printing can also be used individually or in combination to coat the fibers. These fabrication techniques can allow high throughput and large area fabrication of the light-emitting fibers. Through the right selection of the structural layers importantly the emissive layer fibers can be formed with various emitting wavelengths. Fibers can be made to be emissive over the entire length of fiber. However, the above processes can also be altered to enable pixelated LEDs along the length of the fiber (these LEDs can be of the same color or different colors).

Upon fabrication of the light emitting fibers, these fibers which can have various colors and forms, can be integrated into more complex structures. For example, multiple fibers can be braided into fiber bundles. In such a structure, various colors can also be integrated within the same bundle. Furthermore, these fibers or bundles of fibers can be woven into larger area textiles (fabric) that, in certain embodiments, may have multicolor or pixelated components.

The light emitting fibers described herein have numerous uses. For example, they can be incorporated into (e.g., woven into) wearable light emitting fabrics for applications including sports, fashion and military. They can also be utilized in medical applications including neural stimulation for example through optogenetics, light emitting cloth for therapeutic purposes such as treating Jaundice, and medical sensors for example for healthcare monitoring. Applications in agriculture for example include use in grow lights in the form of fibers or fabrics to stimulate plant growth.

In certain embodiments the light emitting fibers can be engineered to be responsive to their surrounding environment. By using different types of nanomaterials for the emissive layer we can add pressure or chemical sensing functionality which would lead to emission in different wavelengths upon sensing.

Additionally, the versatile approach described herein allows for changing the type of nanomaterials used for coatings to engineer the functionalities of the fiber beyond light emitting fibers. Using the same approach, we can coat the fibers to fabricate devices including energy storage, interconnects and sensors in order to assemble them into a smart fabric with a collective functionality. In certain embodiments the same design of fibers can be used for energy generation for example through formation of solar cells).

### Carbon Nanotube Core.

As explained above, in various embodiments the light emitting fibers are produced by coaxially coating carbon nanotube fiber (e.g., a wet-spun carbon nanotube fiber) with materials needed to enable electrically pumped light emission. Carbon nanotube fibers allow for a flexible and yet an electrically conductive support material for the electrically pumped light emitting fibers.

Carbon nanotube fibers suitable for use in the light emitting fibers are described inter alia, in U.S. Patent Publication No: US 2014/0363669 A1, and by Behabtu et al. (2013) Science, 339(6116): 182-186, and Tsentalovich et al. (2017) ACS Appl. Mater. Interfaces, 9: 36189-36196, which are incorporated herein by reference for the carbon nanotube fibers and methods of CNT fiber fabrication described therein.

In certain embodiments, the diameter of the carbon nanotube (CNT) fiber is less than about 50 μm. In certain embodiments the CNT fiber has an average diameter in the range of about 10 μm up to about 500 μm, or up to about 400 μm, or up to about 300 μm, or up to about 200 μm, or up to about 100 μm, or up to about 80 μm or up to about 50 μm, or in the range of about 2 μm up to about 40 μm, or in the range of about 15 μm up to about 35 μm.

In certain embodiments the carbon nanotube (CNT) fibers according may have a high current-carrying capacity of at least about 2000 A/cm, or at least about 10000 A/cm, or at least about 20000 A/cm, or at least about 30000 A/cm, for a CNT fiber 25 μm in diameter. The current carrying capacity is defined here as a maximum current density at which fiber on a glass substrate shows a constant resistance during the experiment (see, e.g., U.S. Patent Pub. No: 2014/0363669 A1, for methods of measuring CNT fiber resistance.

In certain embodiments, for a fiber of 12.5 μm diameter the current carrying capacity is at least about 3000 A/cm, or at least about 50000 A/cm, or at least about 100000 A/cm, or at least about 500000 A/cm. In certain embodiments, for a fiber of 50 μm diameter the current carrying capacity is at least about 500 A/cm, or at least about 5000 A/cm, or at least about 10000 A/cm, or at least about 20000 A/cm.

In certain embodiments the CNT fiber comprises up to 25 wt. % of a charge carrier donating material(s). It is believed that the charge carrier donating material(s) in the CNT fiber may further reduce the resistivity of the CNT fiber.

In certain embodiments the charge carrier donating material may be comprised within the individual carbon nanotubes (in particular when the CNT fiber comprises open ended carbon nanotubes), and/or the charge carrier donating material may be disposed between the individual carbon nanotubes (in particular when the CNT fiber comprises closed carbon nanotubes).

In certain embodiments, the charge carrier donating material may comprise but is not limited to, an acid, preferably a super acid, salts, such as for example CaCl, bromide containing substances and/or iodine.

In certain embodiments the CNT fiber has a modulus of at least about 120 GPa, or at least about 150 GPa, or at least about 200 GPa.

In certain embodiments the CNT fiber has a tensile strength of at least about 0.3 GPa, or at least about 0.8 GPa, or at least about 1.0 GPa, or at least about 1.5 GPa.

In certain embodiments the (CNT) fibers have a resistivity, measured at a temperature of 20° C., less than about 120 μΩ*cm, or less than about 100 μΩ*cm, or less than about 50 μΩ*cm, or less than about 20 μΩ*cm, or less than about 10 μΩ*cm.

In certain embodiments the CNT fiber has a specific electrical conductivity at 20° C. higher than about 0.6×10⁴ Scm²/g, or higher than about 2×10⁴ Scm²/g, or higher than about 1.3×10⁵ Scm²/g. The specific conductivity is calculated as the conductivity divided by the density of the CNT fiber. Electrical conductivity is the reciprocal value of resistivity.

The density of the CNT fiber is determined by dividing the weight of a piece of filament by its volume. In certain embodiments the density of the CNT fiber may be in the range of about 0.3 to about 2.2 g/cm.

In certain embodiments the carbon nanotube fibers (CNTf) have an average tensile strength of about 2.4 GPa and a room temperature electrical conductivity of about 8.5 MS/m, obtained without postspinning doping (see, e.g., Tsentalovich et al. supra.).

In various embodiments the CNT fibers can be fabricated either by processing CNTs via wet-spinning from a CNT solution or by solid-state spinning from an aligned CNT array (see, e.g., Jiang et al. (2002) Nature 419: 801; Alvarez et al. (2015) Carbon, 86: 350-357; Lekawa-Raus et al. (2014) Adv. Funct. Mater. 24: 3661-3682), from entangled cotton-like CNTs (see, e.g., Ci et al. (2007) Adv. Mater. 19: 1719-1723.), or directly from a CNT reaction chamber (see, e.g., Li, et al. (2004) Science, 304:276-278; Nanocomp Technologies. Miralon Yarn, www.nanocomptech.com/yarn).

In certain embodiments the carbon nanotube fibers used in the light emitting fibers described herein are produced by wet spinning. Wet-spinning is used to process highly liquid crystalline (CNT) material, which is consistent with pursuing improved macroscopic electrical and thermal conductivity. Moreover, acid-spun CNTs are inherently p-doped, reducing or removing the need for a separate postprocessing doping step. Therefore, wet-spinning from acid solutions is an effective method to produce high-purity, low defect density, well-ordered CNT fibers and has reached to date the highest levels of multifunctional performance in terms of combined strength and conductivity or continuous scalable manufacturing (see, e.g., Behabtu et al. (2013) Science, 339: 182-186; Piraux et al. (2015) Phys. Rev. B: Condens. Matter Mater. Phys. 92: 085428; Bucossi et al. (2015) ACS Appl. Mater. Interfaces, 7: 27299-27305; and the like).

Particular wet-spinning protocols are described, inter alia, in U.S. Patent Publication No: US 2014/0363669 A1, and by Tsentalovich et al. (2017) ACS Appl. Mater. Interfaces, 9: 36189-36196 which are incorporated herein by reference for the wet-spinning protocols described therein.

Wet-spinning to produce carbon nanotube fibers typically involves supplying a spin-dope comprising carbon nanotubes (CNT) to a spinneret, extruding the spin-dope through at least one spinning hole in the spinneret to form spun CNT fiber(s), coagulating the spun CNT fiber(s) in a coagulation medium to form coagulated CNT fibers. In certain embodiments the fiber(s) are drawn at a draw ratio of at least 1.0 and the carbon nanotubes have an average length of at least 0.5 μm.

In various embodiments, the carbon nanotubes have an average length of at least 1 μm, more preferably at least 2 μm, even more preferably at least 5 μm, even more preferably at least 15 μm, even more preferably at least 20 μm, most preferably at least 100 μm.

In various embodiments the spin-dope may comprise metallic carbon nanotubes and/or semi-conducting carbon nanotubes.

In one illustrative, but non-limiting embodiment, the spin-dope can be formed by dissolving carbon nanotubes in a suitable solvent, such as a super acid (e.g., chlorosulfonic acid). Additionally, in certain embodiments the spin-dope may comprise polymers, coagulants, surfactants, salts, nanoparticles, dyes, or materials that can improve conductivity. In certain embodiments the carbon nanotubes are purified and/or dried before dissolving the carbon nanotubes in the solvent.

In one illustrative, but non-limiting embodiment, the spin-dope comprises 0.2 wt. % to 25 wt. % carbon nanotubes, based on the total weight of the spin-dope, preferably 0.5 wt. % to 20 wt. %, more preferably 1 wt. % to 15 wt. %.

In one illustrative, but non-limiting embodiment, the spin-dope comprises 1 wt % to 6 wt % carbon nanotubes, most preferably 2 wt. % to 6 wt. %. These relatively low concentrations of carbon nanotubes in the spin-dope provide that the resulting CNT fiber has lower resistivity and/or a higher modulus.

In various embodiments, the spin-dope comprising carbon nanotubes is supplied to a spinneret and extruded through at least one spinning hole to obtain spun CNT fiber(s). The spinneret may contain any number of spinning holes, ranging from one spinning hole to manufacture CNT monofilament up to several thousands to produce multifilament CNT yarns.

In one illustrative embodiment of the process to obtain CNT fibers having low resistivity the spinning hole(s) in the spinneret are circular and have a diameter in the range of 10 to 1000 μm, or in the range of 25 to 500 μm, or in the range of 40 to 250 μm.

In various embodiments, the extruded CNT fiber(s), also called spun CNT fiber(s), may be spun directly into a coagulation medium, or guided into a coagulation medium via an air gap. The coagulation medium may be contained in a coagulation bath, or may be supplied in a coagulation curtain. The coagulation medium in the coagulation bath may be stagnant or there may be a flow of coagulation medium inside or through the coagulation bath.

In certain embodiments the spun CNT fibers may enter the coagulation medium directly to coagulate the CNT fibers to increase the strength of the CNT fibers to ensure that the CNT fibers are strong enough to support their own weight. The speed of the CNT fiber(s) in the coagulation medium is in general established by the speed of a speed-driven godet or winder after the CNT fibers have been coagulated and optionally neutralized and/or washed.

In an air gap the spun CNT fiber(s) can be drawn to increase the orientation in the CNT fiber(s) and the air gap avoids direct contact between spinneret and coagulation medium. The speed of the CNT fiber(s) and thus the draw ratio in the air gap is in general established by the speed of a speed-driven godet or winder after the CNT fibers have been coagulated and optionally neutralized and/or washed.

These methods of making the carbon nanotube fibers are illustrative and non-limiting. Using the teaching provided herein and references cited herein, numerous other synthesis protocols will be available to one of skill in the art.

### Emissive Layer.

The light-emissive layer 130 may comprise any material that is capable of sustaining charge carrier transport and also capable of light emission under device driving conditions (e.g., the application of a potential). In certain embodiments the emissive layer comprises an inorganic nanoparticle layer, an inorganic thin film layer, an organic molecule emissive layer, a polymeric emissive layer, and/or a nanoparticle or nanomaterial-polymer composite layer.

In certain embodiments the emissive layer comprises an inorganic nanoparticle layer and/or an inorganic thin film layer. Illustrative inorganic materials suitable for the emissive layer include, but are not limited to, materials based on Group 13-15 element nitrides and yttrium aluminum garnets, or zinc, calcium, or strontium sulfides doped with rare earths. Such materials have been shown to provide high quantum yields and luminescence brightness. Illustrative materials include, but are not limited to aluminium gallium arsenide (AlGaAs), aluminium gallium indium nitride (AlGaInN), aluminium gallium indium phosphide (AlGaInP), aluminium gallium nitride (AlGaN), aluminium gallium phosphide (AlGaP), aluminium nitride (AlN), boron nitride, gallium arsenide (GaAs), gallium arsenide phosphide (GaAsP), gallium arsenide phosphide (GaAsP), gallium arsenide phosphide (GaAsP), gallium(III) nitride (GaN), gallium(III) phosphide (GaP), gallium(III) phosphide (GaP), gallium(III) phosphide (GaP), gallium(III) phosphide (GaP), indium gallium nitride (InGaN), indium gallium nitride (InGaN), indium gallium nitride (InGaN), indium gallium nitride (InGaN), zinc selenide (ZnSe), and the like.

In certain embodiments the inorganic material comprises a material selected from the group consisting of GaP:ZnO, GaP:N, GaAsP:N, AlGaAs/GaAs, AlGaAs/AlGaAs, AlInGaP/GaAs, AlInGaP/GaP, and the like.

In certain embodiments the emissive layer comprises a thin film or nanoparticles comprising a metal halide perovskite, e.g., as described in PCT Publication No: PCT/GB2016/052292, which is incorporated herein by reference for the metal halide perovskites described therein. In certain embodiments the perovskite comprises a material according to the formula CH₃NH₃PbX₃, where X is one or more halides. In certain embodiments the perovskite comprises a material according to the formula CsPbX₃ where X is one or more halides. In certain embodiments the perovskite comprise a material selected from the group consisting of CH₃NH₃PbBr₃, CH₃NH₃PbCl₃, and CH₃NH₃PbI₃. In certain embodiments the perovskite comprise a material selected from the group consisting of CH₃NH₃PbI₃, CH₃NH₃,PbBr₃, CH₃NH₃PbCl₃, CH₃NH₃PbF₃, CH₃NH₃PbBrI₂, CH₃NH₃PbBrCl₂, CH₃NH₃PbIBr₂, CH₃NH₃PbICl₂, CH₃NH₃PbClBr₂, CH₃NH₃PbI₂Cl, CH₃NH₃SnI₃, CH₃NH₃SnBr₃, CH₃NH₃SnCl₃, CH₃NH₃SnF₃, CH₃NH₃SnBrI₂, CH₃NH₃ SnBrCl₂, CH₃NH₃ SnF₂Br, CH₃NH₃SnIBr₂, CH₃,NH₃SnICl₂, CH₃NH₃ SnF₂I, CH₃NH₃SnClBr₂, CH₃NH₃SnI₂Cl, CH₃NH₃SnF₂Cl, and the like.

In certain embodiments the perovskite nanocrystals can be mixed with polymers including, but not limited to PVP, PEO, and the like.

In certain embodiments the emissive layer comprises one or more metal chalcogenides. Illustrative chalcogenides include, but are not limited to metal chalcogenide nanocrystals such as ZnS, ZnSe, ZnTe, CdS, CdSe, CdTe, HgS, HgSe, HgTe, PbS, Pb Se, PbTe, SnS, SnSe, SnTe, CdEuS, CdMnS, Pd₉Se₂, as well as the metal cations including Fe, Co, Ni, Cu, Ag, in compounds such as FeX, CoX, Cu₂X, Ag₂X, where X=S, Se or Te (see, e.g., U.S. Pat. No. 8,137,457 B2, which is incorporated herein by reference for the metal chalcogenides described therein.

In certain embodiments the emissive layer comprises an organic molecule emissive layer and/or or a polymeric emissive layer. Illustrative organic materials include, but are not limited to fluorescent organic compounds and conjugated polymers.

In certain embodiments the emissive layer comprises a conjugated polymer. Such conjugated polymers include, but are not limited to Alq3 (tris(8-hydroxyquinolinato)aluminium), polyphenylenes and derivatives, polyfluorenes and derivatives, polythiophenes and derivatives, polyfluoroene (PF), polyphenylene vinylenes (e.g., polyphenylene PPP) and derivatives (e.g., poly[{2,5-di(3′,7′-dimethyloctyloxy)-1,4-phenylene-vinylene}-co-{3-(4′-(3″,7″-dimethyloctyloxy)phenyl)-1,4-phenylenevinylene}-co-{3-(3′-(3′,7′-dimethyloctyloxy)phenyl)-1,4-phenylenevinylene}] (aka. Super yellow or SY-PPV)), polyvinyl carbazole, polymers containing heteroaromatic rings, and the like. In certain embodiments the emissive layer comprises a poly(p-phenylenevinylene) (PPV), e.g., as described in U.S. Pat. No. 5,247,190. In certain embodiments the PPV has the formula

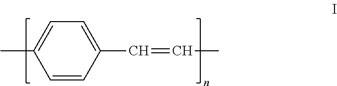

where, in various embodiments, the phenylene ring may optionally carry one or more substituents each independently selected from alkyl (e.g., methyl), alkoxy (e.g., methoxy or ethoxy), halogen (e.g., chlorine or bromine), or nitro. Other conjugated polymers derived from poly(p-phenylenevinylene) are also suitable for use in the emissive layer(s) of the light emitting fibers described herein.

Typical examples of such derivatives include, but are not limited to, polymers derived by:
(i) replacing the phenylene ring in formula (I) with a fused ring system, e.g. replacing the phenylene ring with an anthracene or naphthalene ring system to give structures such as:

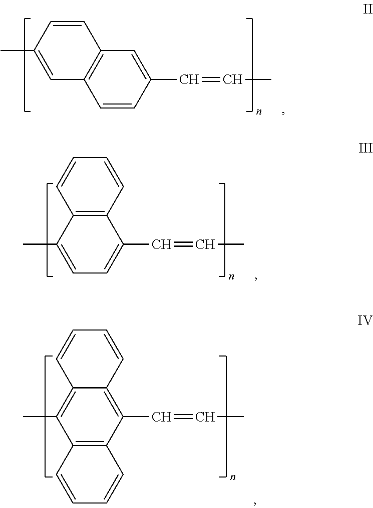

and the like and, in various embodiments these alternative ring systems can also carry one or more substituents of the type described above in relation to the phenylene ring;

(ii) replacing the phenylene ring with a heterocyclic ring system such as a furan ring to give structures such as:

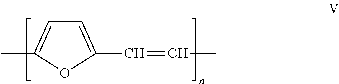

where, in various embodiments, the furan ring may carry one or more substituents of the type described above in relation to phenylene rings; or

(iii) increasing the number of vinylene moieties associated with each phenylene ring (or each of the other alternative ring systems described above in (i) and (ii)) to give structures such as:

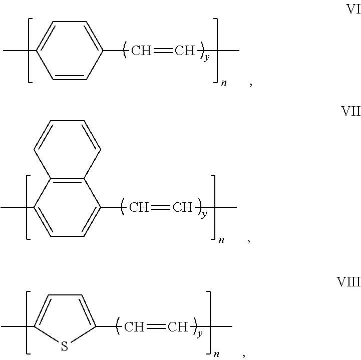

and the like, where y represents 2, 3, 4, 5, 6, 7 . . . . In certain embodiments these ring systems may carry the various substituents described above.

In certain embodiments the emissive layer comprises a light-emissive sublimed molecular film, e.g., as described in U.S. Pat. No. 4,539,507, which is incorporated herein by reference for the emissive materials described therein. Illustrative emissive materials include, but are not limited to epidolidione, 1,1-bis(4-di-p-tolylaminophenyl)cyclohexane, [4,4′-bis[5,7-di(2-methyl-2-butyl)-2-benzoxazolyl]stilbene], [2,5-bis[5,7-di(2-methyl-2-butyl)-2-benzoxazolyl]thiophene], [2,2′-(1,4-phenylenedivinylene)bisbenzothiazole], [2,2′-(4,4′-biphenylene)bisbenzothiazole], [2,5-bis[5-(α,α-dimethylbenzyl)-2-benzoxazolyl]thiophene], [2,5-bis[5,7-di(2-methyl-2-butyl)-2-benzoxazolyl]-3,4-diphenyl-thiophene], and the like.

In one illustrative, but non-limiting embodiment the emissive layer comprise poly[2-methoxy-5-(2-ethylhexyloxy)-1,4-phenylenevinylene] which can effectively be used in combination with poly(3,4-ethylenedioxythiophene)-poly(styrenesulfonate) as a hole transport layer.

Many useful emissive materials include one or more ligands bound to a metal center. A ligand may be referred to as “photoactive” if it contributes directly to the photoactive properties of an organometallic emissive material. A “photoactive” ligand may provide, in conjunction with a metal, the energy levels from which and to which an electron moves when a photon is emitted. Other ligands may be referred to as “ancillary.” Ancillary ligands may modify the photoactive properties of the molecule, for example by shifting the energy levels of a photoactive ligand, but ancillary ligands do not directly provide the energy levels involved in light emission. A ligand that is photoactive in one molecule may be ancillary in another. These definitions of photoactive and ancillary are intended as non-limiting theories.

Illustrative ligands conjugated to a metal center include for example, metal complexes of 8 hydroxyquinoline, where the metal is Zn, Al, Mg, or Li.

Suitable conjugated ligands for use in the emissive layer are well known to those of skill in the art. For example, it has been shown that highly emissive Ir complexes can be formed with two cyclometallated ligands (abbreviated as CAN) and a single monoanionic, bidentate ancillary ligand (LAL). The emission colors from those Ir complexes are strongly dependent on the choice of cyclometallating ligand, ranging from green to red, with room temperature lifetimes on the order of microseconds. OLEDs have been made with (C\hat{ }N)2Ir(L\hat{ }L) phosphor dopants, giving efficient green, yellow or red emission (see, e.g., Lamansky et al. (2001) Inorg. Chem.; Lamansky et. al. (2001) J. Am. Chem. Soc. 121: 4304). Illustrative Ir complexes include but are not limited to ppy, tpy, zq, thp, dpo. C6, bo, bon, bt, op, αbsn, βbsn, tth, pq, and btp (see, e.g., Table 1).

TABLE 1
Illustrative IR complexes.

| | |
|---|---|
| 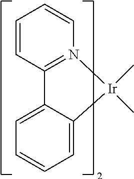 | ppy |
| 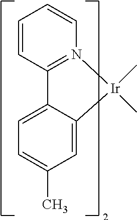 | tpy |
| 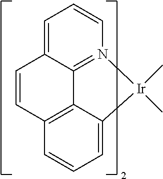 | bzq |
| 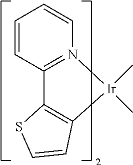 | thp |
| 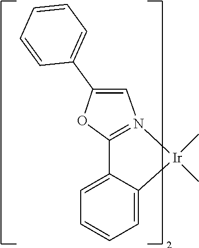 | dpo |
| 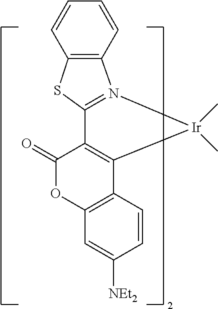 | C6 |
| 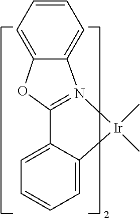 | bo |
| 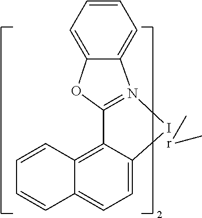 | bon |
| 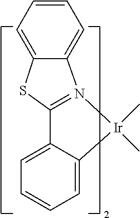 | bt |
| 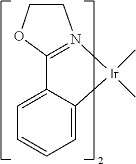 | op |
| 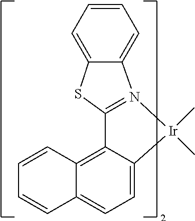 | αbsn |
| 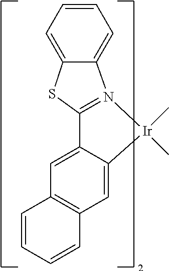 | βbsn |
| 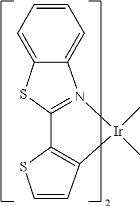 | btth |
| 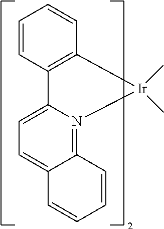 | pq |
| 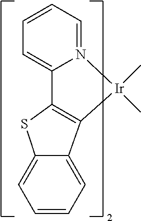 | btp |

In one illustrative embodiment the Ir complex comprises tris(2-phenylpyridine) iridium (Ir(ppy)₃), e.g., as described in U.S. Pat. No. 5,844,363.

In certain embodiments the complex comprises a chemical structure according to the Formula:

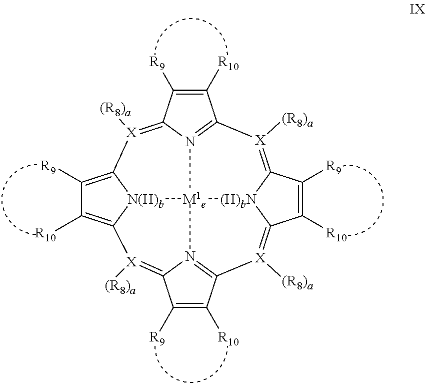

where X is C or N; R₈, R₉ and R₁₀ are each independently selected from the group consisting of hydrogen, alkyl, substituted alkyl, aryl and substituted aryl; wherein R₉ and R₁₀ may be combined together to form a fused ring; M is a divalent, trivalent or tetravalent metal; and a, b and c are each 0 or 1, and where when X is C, then a is 1; when X is N, then a is 0; when c is 1, then b is 0; and when b is 1, c is 0, as described in U.S. Pat. No. 6,303,238 which is incorporated herein by reference for the emissive compounds described therein. In certain embodiments the emissive compound comprises a compound according to Formula IX, where X=C; R₈=phenyl; R9=R10=H; c=0; and b=1. This compound has the chemical name 5,10,15,20-tetraphenyl-21H,23H-porphine (TPP) and is described in U.S. Pat. No. 6,048,630. In certain embodiments the emissive compound comprises a compound according to Formula IX, where M=Pt, a=1, b=0, c=1, X=C, and R₈=H, and R₉=R₁₀=Et (ethyl) forming a compound having the name platinum octaethylporphine (PtOEP).

In certain embodiments the emissive layer comprise trivalent metal quinolate complexes, trivalent metal bridged quinolate complexes, Schiff base divalent metal complexes, tin (iv) metal complexes, metal acetylacetonate complexes, metal bidentate ligand complexes, bisphosphonates, divalent metal maleonitriledithiolate complexes, aromatic and heterocyclic polymers and rare earth mixed chelates, as described in U.S. Pat. No. 5,707,745 which is incorporated herein by reference for the compounds described therein.

The foregoing materials for use in the emissive layers in the light emitting fibers described herein are illustrative and non-limiting. Using the teaching provided herein numerous other materials will be available to one of skill in the art.

### Optional Hole Transport Layer.

In certain embodiments the light emitting fibers 100 described herein comprise a hole transport layer 120 disposed between the carbon nanotube fiber 110 and the emissive layer 130. In certain embodiments the hole transport layer 120 may planarize or wet the anode surface (carbon nanotube fiber surface) so as to provide efficient hole injection from the anode (carbon nanotube fiber) into the hole injecting material.

In certain embodiments the hole transport layer comprise an inorganic thin film and/or a layer of inorganic nanocrystals, or a film of organic molecules, or an organic polymer.

In certain embodiments the hole transport layer comprises an inorganic thin film and/or a layer of inorganic nanocrystals such as Zn, TiO2, CuI, NiO, and the like. In certain embodiments the hole transport layer comprises an inorganic thin film formed by annealing a precursor solution non the fiber such as ZnO.

In certain embodiments the hole transport layer can comprises a composite, e.g., an inorganic nanomaterial such as nanoparticles supported in a matrix material (e.g., a polymer). Thus, for example, in certain embodiments the hole transport layer can comprise perovskite nanoparticles (e.g., crystals) in a matrix material (e.g., a polymer matrix).

In certain embodiments the hole transport layer comprises a film of organic molecules, and/or an organic polymer.

Illustrative, but non-limiting examples of organic compounds for use in hole transport layers include arylamine compounds such as α-NPD and TPD, carbazole derivatives, such as CBP and mCP, and PEDOT:PSS or poly(3,4-ethylenedioxythiophene) polystyrene sulfonate as shown below.

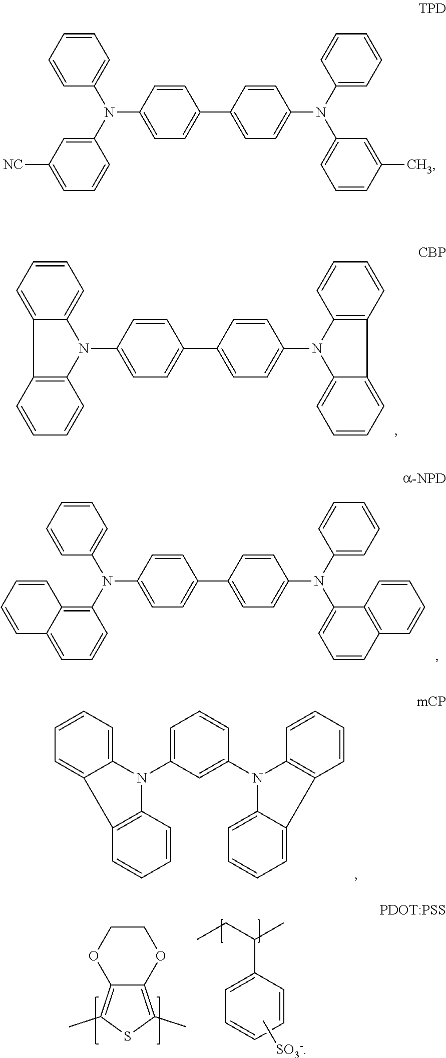

Other examples of materials for use in the hole transport layers, when present, in the in light emitting fibers described herein include, but are not limited to, those shown in Table 2 below.

TABLE 2
Illustrative, but non-limiting examples of hole transport layer materials

| Class | Illustrative structures |
|---|---|
| Starburst triamines | 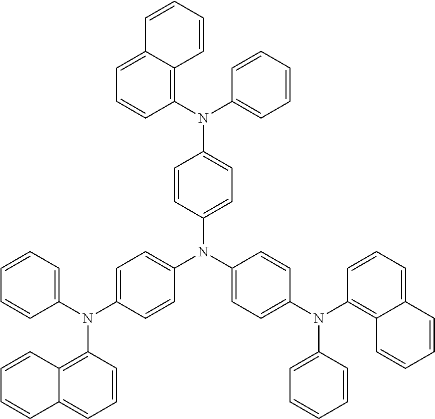 [SMILES: c1ccc(N(c2ccc(N(c3ccc(N(c4ccccc4)c4cccc5ccccc45)cc3)c3ccc(N(c4ccccc4)c4cccc5ccccc45)cc3)cc2)c2cccc3ccccc23)cc1] |
| CFx fluorohydrocarbon | —[CHₓF_{y}]ₙ— |
| polymer | |
| Traiarylamine or polythiophene polymers with conductivity dopants | 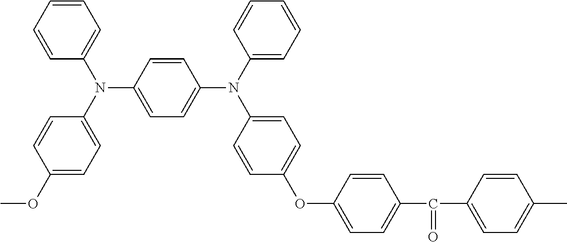 |
| | 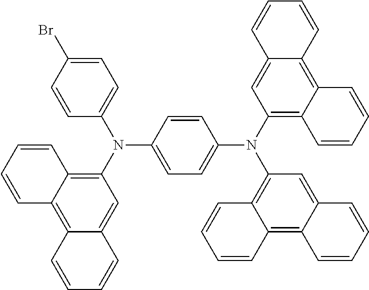 [SMILES: Brc1ccc(N(c2ccc(N(c3cc4ccccc4c4ccccc34)c3cc4ccccc4c4ccccc34)cc2)c2cc3ccccc3c3ccccc23)cc1] |
| | 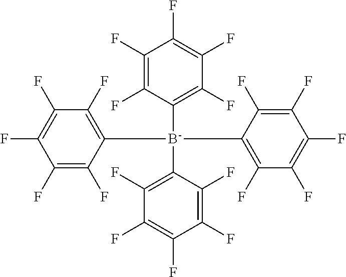 [SMILES: Fc1c(F)c(F)c([B-](c2c(F)c(F)c(F)c(F)c2F)(c2c(F)c(F)c(F)c(F)c2F)c2c(F)c(F)c(F)c(F)c2F)c(F)c1F] |
| Arylamines complexed with metal oxides such as molybdenum and tungsten oxides | 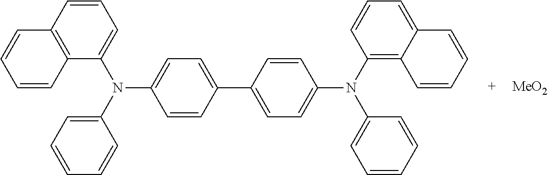 [SMILES: "MeO2" ; c1ccc(N(c2ccc(-c3ccc(N(c4ccccc4)c4cccc5ccccc45)cc3)cc2)c2cccc3ccccc23)cc1] |
| p-type semiconducting organic complexes | 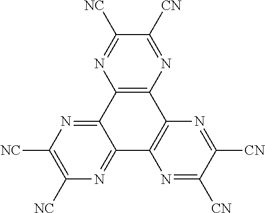 [SMILES: N#Cc1nc2c3nc(C#N)c(C#N)nc3c3nc(C#N)c(C#N)nc3c2nc1C#N] |
| Triarylamines (e.g., TPD, C-NPD) | 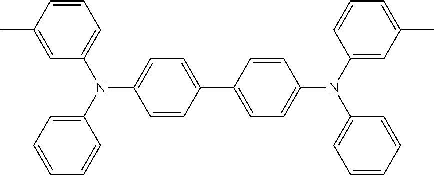 |
| | 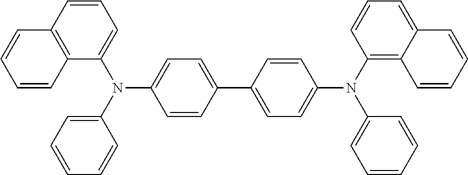 [SMILES: c1ccc(N(c2ccc(-c3ccc(N(c4ccccc4)c4cccc5ccccc45)cc3)cc2)c2cccc3ccccc23)cc1] |
| | 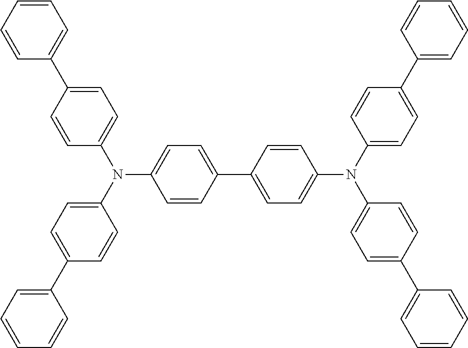 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1] |
| | 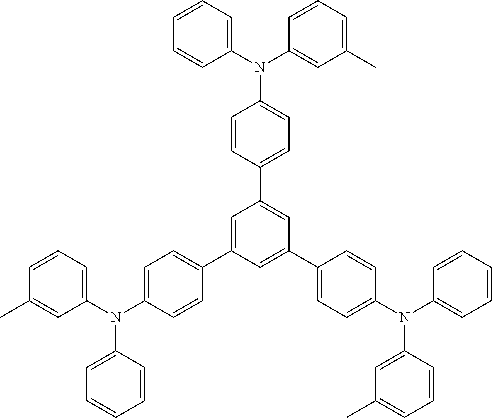 [SMILES: Cc1cccc(N(c2ccccc2)c2ccc(-c3cc(-c4ccc(N(c5ccccc5)c5cccc(C)c5)cc4)cc(-c4ccc(N(c5ccccc5)c5cccc(C)c5)cc4)c3)cc2)c1] |
| | 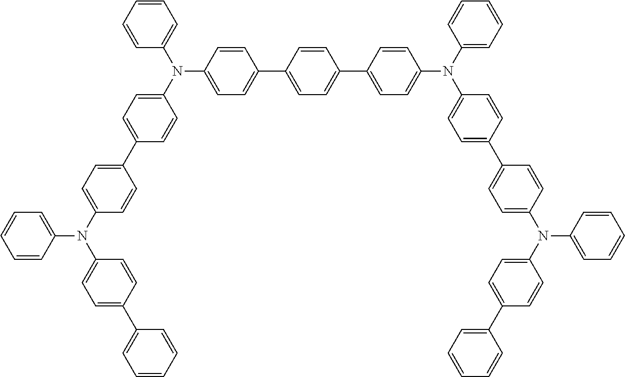 [SMILES: c1ccc(-c2ccc(N(c3ccccc3)c3ccc(-c4ccc(N(c5ccccc5)c5ccc(-c6ccc(-c7ccc(N(c8ccccc8)c8ccc(-c9ccc(N(c%10ccccc%10)c%10ccc(-c%11ccccc%11)cc%10)cc9)cc8)cc7)cc6)cc5)cc4)cc3)cc2)cc1] |
| | 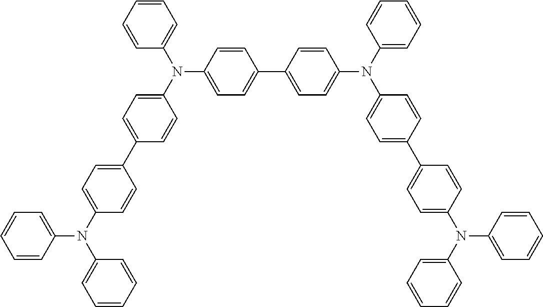 [SMILES: c1ccc(N(c2ccccc2)c2ccc(-c3ccc(N(c4ccccc4)c4ccc(-c5ccc(N(c6ccccc6)c6ccc(-c7ccc(N(c8ccccc8)c8ccccc8)cc7)cc6)cc5)cc4)cc3)cc2)cc1] |
| Triaylamine on spirofluorene core | 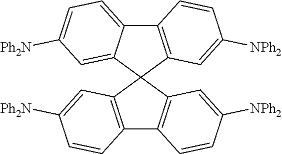 |
| Arylamine carbazole compounds | 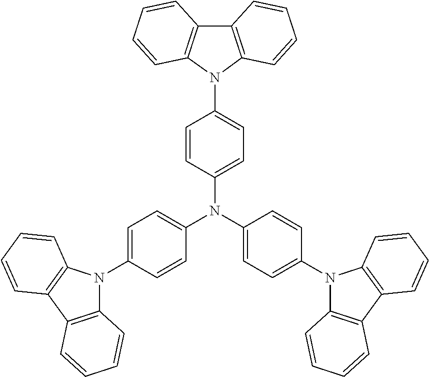 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1] |
| Triarylamine with (di)benzothiophene/ (di)benzofuran | 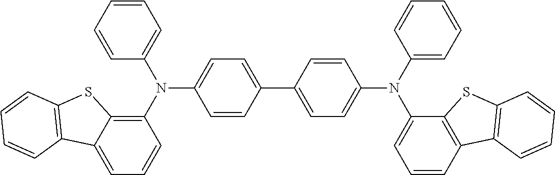 [SMILES: c1ccc(N(c2ccc(-c3ccc(N(c4ccccc4)c4cccc5c4sc4ccccc45)cc3)cc2)c2cccc3c2sc2ccccc23)cc1] |
| Indolocarbazoles | 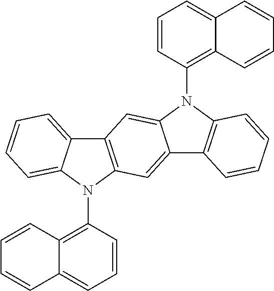 [SMILES: c1ccc2c(-n3c4ccccc4c4cc5c(cc43)c3ccccc3n5-c3cccc4ccccc34)cccc2c1] |
| Isoindole compounds | 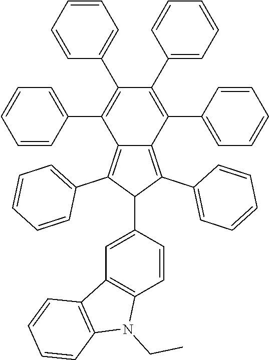 [SMILES: CCn1c2ccccc2c2cc(C3C(c4ccccc4)=c4c(-c5ccccc5)c(-c5ccccc5)c(-c5ccccc5)c(-c5ccccc5)c4=C3c3ccccc3)ccc21] |
| Metal carbene complexes | 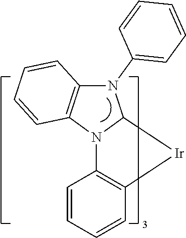 |

Other illustrative, but non-limiting hole transporting compounds include, but are not limited to poly(9-vinylcarbazole) (PVK), polybutadiene (PBD), poly(3-hexylthiophene), and 2,2′,7,7′-Tetrakis(N,N-di-p-methoxyphenylamine)-9,9′-spirobifluorene (spiro-OMeTAD), and the like.

The foregoing materials for use in the hole transport layers, when present, in the light emitting fibers described herein are illustrative and non-limiting. Using the teaching provided herein numerous other materials will be available to one of skill in the art.

### Optional Hole Injection Layer.

In certain embodiments the light emitting fibers 100 described herein can optionally include a hole injection layer (HIL) 160 disposed between, for example, the (carbon nanotube fiber) 110 and the hole transport layer. It will be recognized that, in certain embodiments, the anode need not be the carbon nanotube fiber, in which instance, the hole injection layer can be disposed between the functional anode and the hole transport layer.

In certain embodiments the carbon nanotube fiber acts as an anode. However, the anode depending on the particular design of the device (particular materials used) does not necessarily need to be the carbon nanotube. In certain embodiments the hole injection layer can planarize or wet the carbon nanotube fiber surface so as to provide efficient hole injection from the anode (carbon nanotube fiber) into the hole transporting material. A hole injection layer may also have a charge carrying component having HOMO (highest occupied molecular orbital) energy levels that favorably match up, as defined by their relative ionization potential (IP) energies, with the adjacent anode layer on one side of the HIL and the hole transporting layer on the opposite side of the HIL. The “charge carrying component” is the material responsible for the HOMO energy level that actually transports holes. In certain embodiments this component may comprise the base material of the HIL, or it may be a dopant. Using a doped HIL allows the dopant to be selected for its electrical properties, and the host to be selected for morphological properties such as wetting, flexibility, toughness, etc. Preferred properties for the HIL material are such that holes can be efficiently injected from the anode (carbon nanotube fiber) into the HIL material. In particular, in certain illustrative, but non-limiting embodiments, the charge carrying component of the HIL has an IP not more than about 0.7 eV greater that the IP of the anode (carbon nanotube fiber) material. In particular, in certain illustrative, but non-limiting embodiments, the charge carrying component has an IP not more than about 0.5 eV greater than the anode (carbon nanotube fiber). Similar considerations apply to any layer into which holes are being injected.

In certain embodiments HIL materials can further distinguished from conventional hole transporting materials that are typically used in the hole transporting layer of an OLED in that such HIL materials may have a hole conductivity that is substantially less than the hole conductivity of conventional hole transporting materials. In certain embodiments the thickness of the HIL, when present, may be thick enough to help planarize or wet the surface of the anode layer (carbon nanotube fiber). For example, an HIL thickness of as little as 10 nm may be acceptable for a very smooth fiber surface. However, where anode surfaces tend to be very rough, a greater thickness for the HIL may be desired in some cases. Examples of hole injecting materials that can be used are shown in Table 3 below

TABLE 3
Illustrative, but non-limiting examples of hole injection layer materials

| Class | Illustrative Formulas |
|---|---|
| Phthalocyanine and porphryin compounds | 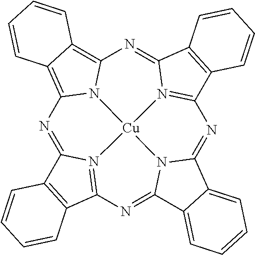 |
| Starburst triarylamines | 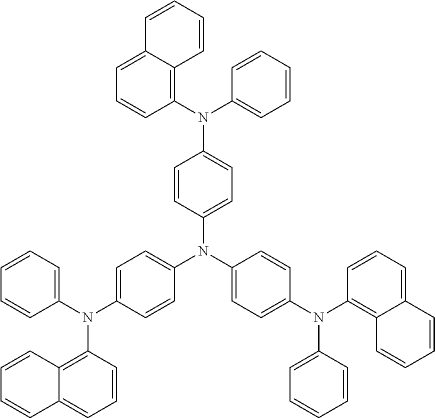 [SMILES: c1ccc(N(c2ccc(N(c3ccc(N(c4ccccc4)c4cccc5ccccc45)cc3)c3ccc(N(c4ccccc4)c4cccc5ccccc45)cc3)cc2)c2cccc3ccccc23)cc1] |
| CFₓFluorohydrocarbon | —[CHₓF_{y}]ₙ |
| polymer | |
| Conducting polymers (e.g., PEDOT:PSS, polyaniline, polypthiophene) | 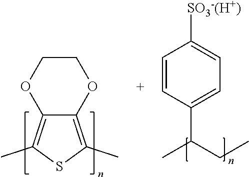 |
| | 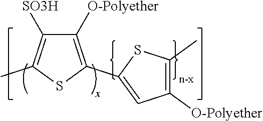 |
| Phosphonic acid and silane SAMs | 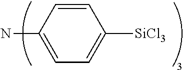 |
| Triarylamine or polythiophene polymers with conductivity dopants | 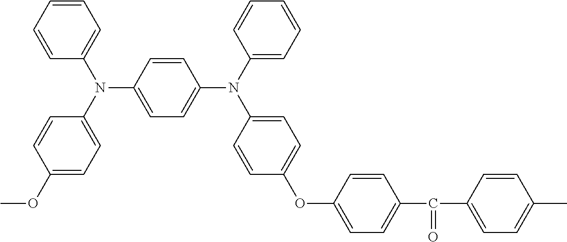 |
| | 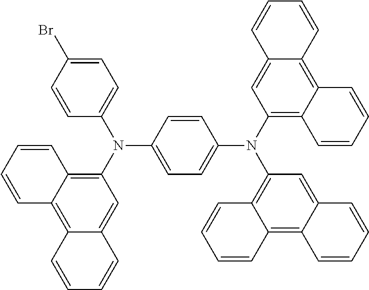 [SMILES: Brc1ccc(N(c2ccc(N(c3cc4ccccc4c4ccccc34)c3cc4ccccc4c4ccccc34)cc2)c2cc3ccccc3c3ccccc23)cc1] |
| | 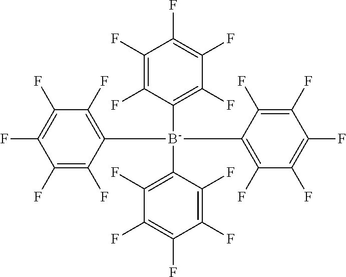 [SMILES: Fc1c(F)c(F)c([B-](c2c(F)c(F)c(F)c(F)c2F)(c2c(F)c(F)c(F)c(F)c2F)c2c(F)c(F)c(F)c(F)c2F)c(F)c1F] |
| Arylamines complexed with metal oxides such as molybdenum and tungsten oxides | 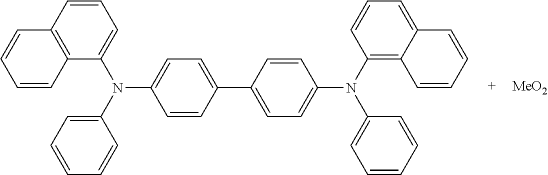 [SMILES: "MeO2" ; c1ccc(N(c2ccc(-c3ccc(N(c4ccccc4)c4cccc5ccccc45)cc3)cc2)c2cccc3ccccc23)cc1] |
| P-type semiconducting organic complexes | 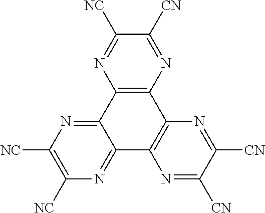 [SMILES: N#Cc1nc2c3nc(C#N)c(C#N)nc3c3nc(C#N)c(C#N)nc3c2nc1C#N] |
| Metal organometallic complexes | 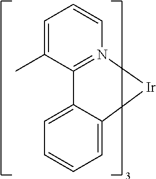 |
| Cross-linkable compounds | 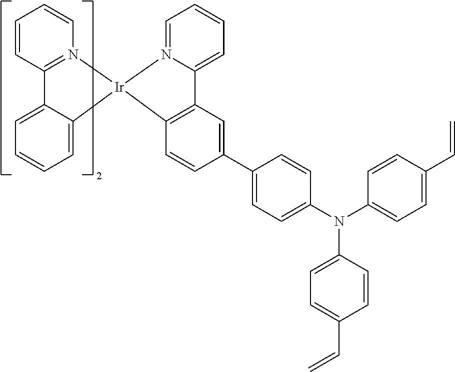 |
| Organosilane compounds | 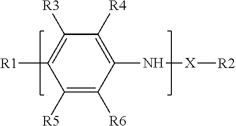 |
| | where R₁ and R₂ independently represent a hydrogen atom, a |
| | halogen atom, a hydroxyl group, an amino group, a silanol |
| | group, a thiol group, a carboxyl group, a phosphate group, a |
| | phosphoric acid ester group, an ester group, a thioester group, |
| | an amide group, a nitro group, a monovalent hydrocarbon |
| | group, an organoxy group, an organosilyl group, an |
| | organothio group, an acyl group, or a sulfone group; and R³ |
| | to R⁶ independently represent a hydrogen atom, a halogen |
| | atom, a hydroxyl group, an amino group, a silanol group, a |
| | thiol group, a carboxyl group, a phosphate group, a |
| | phosphoric acid ester group, an ester group, a thioester group, |
| | an amide group, a nitro group, a monovalent hydrocarbon |
| | group, an organoxy group, an organoamino group, an |
| | organosilyl group, an organothio group, an acyl group, or a |
| | sulfone group |

In certain embodiments the hole injection layer, when present, can comprise a discrete layer between the carbon nanotube fiber and the hole transport layer (when present). In certain embodiments the hole injection layer and the hole transport layer can be integrated into a single continuous layer and in certain embodiments the hole transport layer can additionally function as a hole injection layer. In certain embodiments the hole injection layer forms a gradient that transitions into a hole transport layer.

The foregoing materials for use in the hole injection layers, when present, in the light emitting fibers described herein are illustrative and non-limiting. Using the teaching provided herein numerous other materials will be available to one of skill in the art.

### Optional Electron Transport Laver.

In certain embodiments the light emitting fibers 100 described herein comprise an electron transport layer 140 disposed between the emissive layer 130 and the outer conductor 150. In certain embodiments the electron transport layer 140 may include a material capable of transporting electrons. Electron transport layer 140 may be intrinsic (undoped), or doped. Doping can be used to enhance conductivity. Tris(8-hydroxyquinolinato)aluminium (Alq₃ is an example of an intrinsic electron transport layer. An example of an n-doped electron transport layer is BPhen doped with Li at a molar ratio of, e.g., 1:1, as disclosed in United States Patent Application Publication No. 2003/02309890, which is incorporated by reference for the electron transport materials described therein.

In certain embodiments, the charge carrying component of the electron transport layer may be selected such that electrons can be efficiently injected from the cathode into the LUMO (lowest unoccupied molecular orbital) energy level of the electron transport layer. The “charge carrying component” is the material typically responsible for the LUMO energy level that actually transports electrons. In various embodiments this component may be the base material, or it may be a dopant. The LUMO energy level of an organic material may be generally characterized by the electron affinity of that material and the relative electron injection efficiency of a cathode may be generally characterized in terms of the work function of the cathode material. This means that, in certain embodiments, the properties of an electron transport layer and the adjacent cathode may be specified in terms of the electron affinity of the charge carrying component of the ETL and the work function of the cathode material. In certain illustrative, but non-limiting embodiments, so as to achieve high electron injection efficiency, the work function of the cathode material is not greater than the electron affinity of the charge carrying component of the electron transport layer by more than about 0.75 eV, or by not more than about 0.5 eV. Similar considerations apply to any layer into which electrons are being injected.

In certain embodiments the electron transport layer comprises an inorganic thin film and/or a layer of inorganic nanocrystals, or a film of organic molecules, or an organic polymer.

In certain embodiments the electron transport layer comprises an inorganic thin film and/or a layer of inorganic nanocrystals such as Zn, TiO₂, CuI, NiO, and the like. In certain embodiments the electron transport layer comprises an inorganic thin film formed by annealing a precursor solution non the fiber such as ZnO.

In certain embodiments the electron transport layer comprises a film of organic molecules, and/or an organic polymer. Illustrative, but non-limiting examples of organic materials suitable for use in the electron transport layer, when present, are shown in Table 4.

TABLE 4
Illustrative, but non-limiting examples of electron transport layer materials

| Name | Structure |
|---|---|
| 3TPYMB 3,3′,3″-[Borylidynetris(2,4,6- trimethyl-3,1- phenylene)]tris[pyridine], Tri[3- (3-pyridyl)mesityl]borane, Tris(2,4,6-trimethyl-3-(pyridin-3- yl)phenyl)borane | 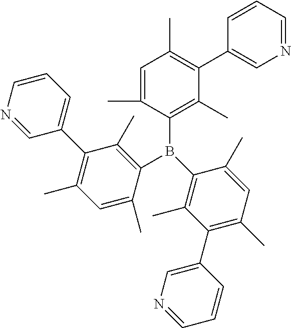 [SMILES: Cc1cc(C)c(-c2cccnc2)c(C)c1B(c1c(C)cc(C)c(-c2cccnc2)c1C)c1c(C)cc(C)c(-c2cccnc2)c1C] |
| B3PYMPM 4,6-Bis(3,5-di(pyridin-3- yl)phenyl)-2-methylpyrimidine, 4.6-Bis(3,5-di-3- pyridinylphenyl)-2- niethylpyrimidine, 4,6-Bis(3,5- di-3-pyridylphenyl)-2- melhylpyrimidine | 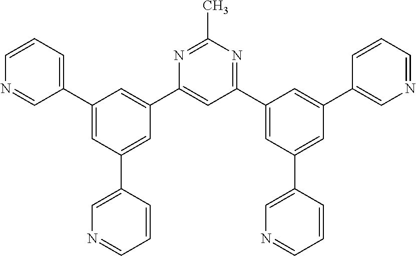 [SMILES: Cc1nc(-c2cc(-c3cccnc3)cc(-c3cccnc3)c2)cc(-c2cc(-c3cccnc3)cc(-c3cccnc3)c2)n1] |
| B3PyPB 1,3-Bis(3,5-dipyrid-3- ylphenyl)benzene, 1,3-Bis[3,5- di(pyridin-3-yl)phenyl]benzene, 3,3′,3″,3″′-[1,1′:3′,1″-terphenyl]- 3,3″,5,5″-tetrayltetrakispyridine. 3,5,3″,5″-Tetra-3-pyridyl- 1,1′:3,1″-terphenyl, BmPyPhB | 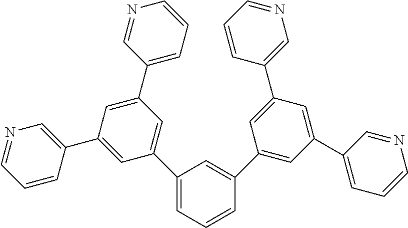 [SMILES: c1cncc(-c2cc(-c3cccnc3)cc(-c3cccc(-c4cc(-c5cccnc5)cc(-c5cccnc5)c4)c3)c2)c1] |
| Bathocuproine | 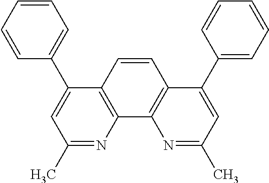 [SMILES: Cc1cc(-c2ccccc2)c2ccc3c(-c4ccccc4)cc(C)nc3c2n1] |
| Bathophenanthroline | 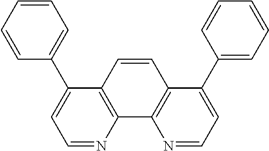 [SMILES: c1ccc(-c2ccnc3c2ccc2c(-c4ccccc4)ccnc23)cc1] |
| 3-(Biphenyl-4-yl)-5-(4-tert- butylphenyl)-4-phenyl-4H-1,2,4- triazole | 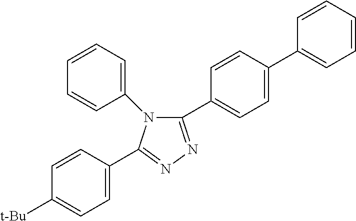 [SMILES: CC(C)(C)c1ccc(-c2nnc(-c3ccc(-c4ccccc4)cc3)n2-c2ccccc2)cc1] |
| 3,5-Bis(4-tert-butylphenyl)-4- phenyl-4H-1,2,4-triazole | 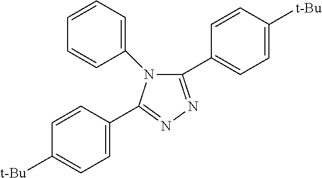 [SMILES: CC(C)(C)c1ccc(-c2nnc(-c3ccc(C(C)(C)C)cc3)n2-c2ccccc2)cc1] |
| Bis(8-hydroxy-2- methylquinoline)-(4- phenylphenoxy)aluminum | 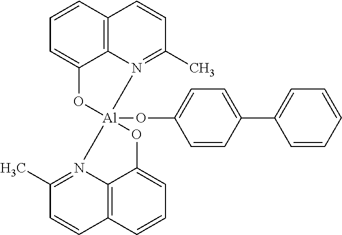 |
| 2,5-Bis(1-naphthyl)-1,3,4- oxadizole | 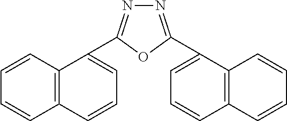 [SMILES: c1ccc2c(-c3nnc(-c4cccc5ccccc45)o3)cccc2c1] |
| BPy-TP2 2,7-Bis(2,2′-bipyridin-5- yl)triphenylene, 2,7-Di(2,2′- bipyridin-5-yl)triphenylene, 5-(7- [2,2′-Bipyridin]-5-yl-2- triphenylenyl)-2,2′-bipyridine | 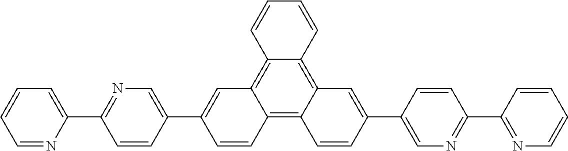 [SMILES: c1ccc(-c2ccc(-c3ccc4c5ccc(-c6ccc(-c7ccccn7)nc6)cc5c5ccccc5c4c3)cn2)nc1] |
| 2-(4-tert-Butylpheny1)-5-(4- biphenylyl)-1,3,4-oxadiazole | 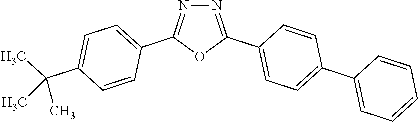 [SMILES: CC(C)(C)c1ccc(-c2nnc(-c3ccc(-c4ccccc4)cc3)o2)cc1] |
| 3,5-Dipheny1-4-(1-naphthyl)-1H- 1,2,4-triazole | 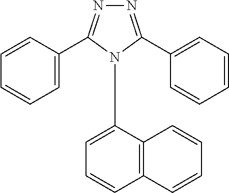 [SMILES: c1ccc(-c2nnc(-c3ccccc3)n2-c2cccc3ccccc23)cc1] |
| 8-Hydroxyquinolinato)lithium, (B-Quinolinolato)lithium, 8- Hydroxyquinoline lithium, 8- Quinolinol lithium salt | 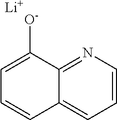 [SMILES: [Li+] ; [O-]c1cccc2cccnc12] |
| PFN-DOF Poly[(9,9-bis(3′-(N,N- dimethylainino)propyl)-2,7- fluorene)-alt-2,7-(9,9- dioctylfluorene)] | 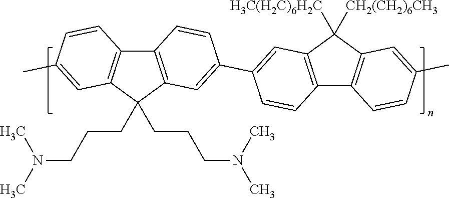 |
| TBP3 2,5,8,11 -Tetrakis(1,1- dimethylethyl)perylenc, 2,5,8,11- Tetra-tert-butylperylene | 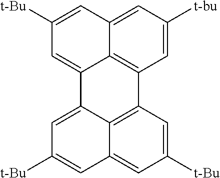 |
| TmPyPB 1,3,5-Tri(m-pyridin-3- ylphenyl)benzene, 1,3,5-Tris(3- pyridyl-3-phenyl)benzene, 3,3′- [5′-[3-(3- pyridinyl)phenyl][1,1′:3′,1″- terphenyl]-3,3″-diyl]bispyridine | 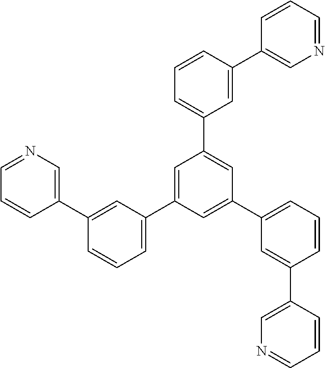 [SMILES: c1cncc(-c2cccc(-c3cc(-c4cccc(-c5cccnc5)c4)cc(-c4cccc(-c5cccnc5)c4)c3)c2)c1] |
| TpBi 2,2′,2″-(1,3,5-Benzinetriyl)- tris(1-phenyl-1-H- benzimidazole) | 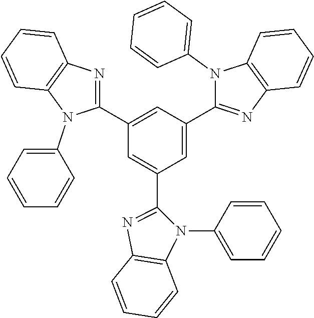 [SMILES: c1ccc(-n2c(-c3cc(-c4nc5ccccc5n4-c4ccccc4)cc(-c4nc5ccccc5n4-c4ccccc4)c3)nc3ccccc32)cc1] |
| Tris-(8- hydroxyquinoline)aluminum | 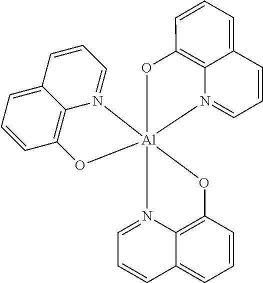 |
| Tris-(8- hydroxyquinoline)aluminum | 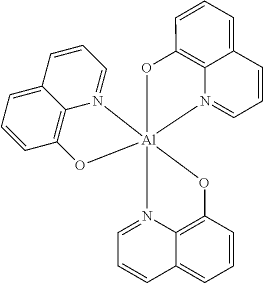 |
| 1,3,5-tris(N | |
| phenylbenzimidazol-2- | |
| yl)benzene | |
| star-shaped 1,3,5-triazine | |
| derivatives: | |
| 2,4,6-tris(biphenyl-3-yl)-1,3,5- | |
| triazine (T2T), | |
| 2,4,6-tris(triphenyl-3-yl)-1,3,5- | |
| triazine (T3T) | |
| 2,4,6-tris(9,90-spirobifluorene- | |
| 2-yl)-1,3,5-triazine (TST)—as | |
| PMMA-TiO2 polymeric | |
| nanocomposite | |

The foregoing materials for use in the electron transport layers, when present, in the light emitting fibers described herein are illustrative and non-limiting. Using the teaching provided herein numerous other materials will be available to one of skill in the art.

### Optional Electron Injection Layer.

In certain embodiments the light emitting fibers 100 described herein can optionally include an electron injection layer (EIL) 180 disposed between, for example, the outer electrode) 170 and the electron transport layer. It will be recognized that, in certain embodiments, the cathode need not be the outer electrode, in which instance, the electron injection layer can be disposed between the functional cathode and the electron transport layer (when present). In certain embodiments the electrode injection layer can planarize or wet the electrode surface so as to provide electron injection from the cathode into the electron transporting material.

It is generally recognized that the injection of charges into an active layer of an organic light-emitting diode (OLED) is determined, at least in part, by the energetic injection barrier formed at the device interfaces. An electron injection layer can effectively decrease the injection barrier thereby increasing the efficiency of the light emitting diode.

Electrode injection materials are well-known to those of skill in the art. Illustrative electron injection materials include, but are not limited to zinc oxide (ZnO), 2-(2,4,6-Trimethoxyphenyl)-1,3-dimethyl-1H-benzoimidazol-3-ium (R3), (2-(2-methoxyphenyl)-1,3-dimethyl-1H-benzoimidazol-3-ium (o-MeO-DMBI or R1), LiF, PEIE, and the like.

The foregoing electron injection materials are illustrative and non-limiting. Using the teaching provided herein numerous other electron injection materials will be available to one of skill in the art.

### Outer Electrode.

In various embodiments the light emitting fibers 100 contemplated herein comprise a conductive outer layer 150 (e.g., a cathode). The conductive outer layer can comprise any suitable material or combination of materials known to the art, such that cathode 150 is capable of conducting electrons and injecting them into the other layers of the device 100.

Metals and metal oxides are examples of suitable cathode materials. In certain embodiments the conductive outer layer 150 may be a single layer, or may have a compound structure. In certain embodiments the conductive outer layer 150 can comprise a thin metal layer and a thicker conductive metal oxide layer. Illustrative martials for use in the conductive outer layer include, but are not limited to include indium tin oxide (ITO), indium zinc oxide (IZO), and other materials known to the art (see, e.g., U.S. Pat. Nos. 5,703,436; 5,707,745; 6,548,956; and 6,576, 134, which are incorporated by reference for the cathode materials described therein. In certain embodiments the conductive outer layer can be formed of metallic or doped semiconducting nanoparticles, in-organic thin-films or polymeric layers. Examples include an interconnected mesh of silver nanowires, gold nanowires, carbon nanotube, graphene, PEDOT:PSS, etc. In certain embodiments metal-polymer composites are also possible examples for the top contact (electrode).

### Fabrication of Light Emitting Fibers.

In certain illustrative, but non-limiting embodiments the carbon nanotube fibers used in the light emitting fibers described herein can be produced by processing CNTs via wet-spinning from a CNT solution or by solid-state spinning from an aligned CNT array, from entangled cotton-like CNTs, or directly from a CNT reaction chamber.

Typically, particular for scale-up, the CNT fibers used in the light emitting fibers described herein are produced by processing CNTs via wet-spinning from a CNT solution. Wet-spinning to produce carbon nanotube fibers typically involves supplying a spin-dope comprising carbon nanotubes (CNT) to a spinneret, extruding the spin-dope through at least one spinning hole in the spinneret to form spun CNT fiber(s), coagulating the spun CNT fiber(s) in a coagulation medium (a non-solvent) to form a solid CNT fiber. The thickness of the fiber can be tuned by controlling the CNT concentration and the spinneret size. Following the coagulation step the fibers are collected on a winding drum rotating at a velocity greater than the spinning velocity to ensure tension along the fiber which leads to a unidirectional alignment of CNTs within the fiber structure (along the fiber axis). Fluid phase processing of CNTs using, e.g., chlorosulfonic acid as the solvent offers a stable route for p-doping of CNTs in the fibers structure that makes them an ideal candidate material as an electrode in the LED design. The as-synthesized fibers can also be doped through techniques such as vapor phase implantation, solution-based diffusion and coating to acquire the desired and tunable electrical properties (p-type vs. n-type doping).

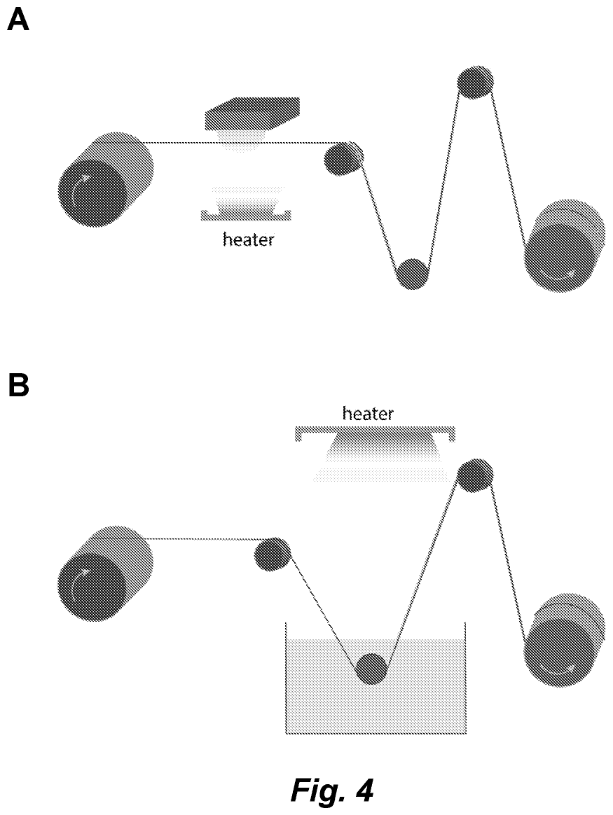

In certain embodiments illustrative, but non-limiting embodiments, the CNT fiber which serves as a charge injection electrode is coated with subsequent layers needed in the light emitting fiber through a roll-to-roll liquid-phase processing technique such as that shown in FIG. 4. In this process, the fiber is held under tension using two winding drums rotating at the same speed but in different directions. The fiber is then passed through a solution of the desired material to be coated. Extra drums are implemented to guide the fiber and ensure an appropriate receding angle at the coating stage. Through use of a motorized roller the speed at which the fiber moves through the solution is controlled to tune the thickness achieved (varying between tens to hundreds of nanometers). Depending on the thickness desired, multiple passes may also be necessary. Following each coating step, the fiber passes through a furnace to be annealed at the appropriate temperature as needed. The entire coating process can take place in an inert environment such as nitrogen or argon.

The process outlined above provides an example of all-solution processable fabrication scheme for the proposed light emitting fibers. Suitable fabrication techniques however are not limited to this process. Beyond the roll-to-roll technique described above, other coating processes including dip-coating, spray-coating, electrodeposition, electroplating, high-vacuum deposition techniques such as sputtering and evaporation, spinning and printing can also be used individually or in combination to coat the fibers. These fabrication techniques can allow high throughput and large area fabrication of the light-emitting fibers. Through the right selection of the structural layers importantly the emissive layer fibers can be formed with various emitting wavelengths. Fibers can be made to be emissive over the entire length of fiber. However, the above processes can also be altered to enable pixelated LEDs along the length of the fiber (these LEDs can be of the same color or different colors).

### EXAMPLES

The following examples are offered to illustrate, but not to limit the claimed invention.

### Example 1

### Fabrication of a Light Emitting Fiber

In one illustrative embodiment, a carbon nanotube fiber fabricated as described above—(see, e.g., U.S. Patent Publication No: US 2014/0363669 A1; Behabtu et al. (2013) Science, 339(6116): 182-186; Tsentalovich et al. (2017) ACS Appl. Mater. Interfaces, 9: 36189-36196) is held under tension using two spools that are fixed. Then using a syringe pump that acts as a motorized arm, we move a capillary tube with a droplet hanging from it. Since the diameter of the fiber is much smaller than the droplet size we the fiber is thereby effectively dipped into the solution comprising the droplet. Instead of pulling the fiber through the liquid we move the droplet along the fiber to coat the fiber with the solution at any desired speed and for as many rounds of coating as desired (see, e.g., FIG. 4, panel A).

All the coatings were done over a heat source (e.g., a hot plate). This results in the coating to be annealed immediately to stop the crystal growth. This results in a more uniform conformal coating of the thin film crystal consisting of smaller crystals because of the immediate annealing.

In another illustrative, but non-limiting, embodiment, particularly for industrial scale fabrication, the fiber can be pulled through the liquid as illustrated in FIG. 4, panel B.

### Annealing the Coating

In one illustrative, but non-limiting embodiment, the PEO-perovskite precursor solution is prepared at the ratio of 5:500 mg/mL concentrations. First, the MAPbBr₃ precursor solution is prepared by mixing MABr and PbBr₂ at a molar ratio of 1:1.5 in DMF at room temperature. Then 5 mg of PEO with Mw=5000,000 is mixed with 1 ml of the perovskite precursor solution to make a 5-500 mg/mL PEO-perovskite solution. The PEO-perovskite solution was first mixed overnight at 50° C. on a hot plate. Before coating the solution on the fiber, the solution was heated at 50° C. and mixed for 72 hrs. 20 microliters of the solution was placed on a round capillary tube. The fiber was held under tension and passing through the droplet over a hot plate at 100° C. This step could be alternatively done by passing the fiber through a bath of the same solution over a heater at 50° C.

The hanging droplet method was used to avoid using large amounts of solution in the lab scale synthesis. The solution was coated on the fiber about 20 times at 3 cm/min while the fiber was suspended over a hot plate. Following that, the fiber was annealed for 5-10 min more at this temperature to ensure that all the crystals were grown and the solvent fully evaporated. Then a 15 microliter droplet of the silver nanowire solution was placed on a round capillary tube and coated with the same method but only for 3 times at the same speed of 3 cm/min to form a thin percolated mesh of nanowires as the transparent electrode on top of the PEO-perovskite layer. The fiber was then annealed at 120° C. for 10 min.

It is noted that in one illustrative embodiment, the ratio of the polymer to perovskite precursor in the solution was 5 mg/ml:500 mg/ml. We found that this concentration to be the optimal for producing a uniform layer, but this can vary with the reagents used.

It is understood that the examples and embodiments described herein are for illustrative purposes only and that various modifications or changes in light thereof will be suggested to persons skilled in the art and are to be included within the spirit and purview of this application and scope of the appended claims. All publications, patents, and patent applications cited herein are hereby incorporated by reference in their entirety for all purposes.

What is claimed is:

1. A light emitting fiber, said fiber comprising:
a conductive carbon nanotube fiber;
an emissive layer surrounding said carbon nanotube fiber; and
a conductive outer layer disposed outside said emissive layer.

2. The light emitting fiber of claim 1, wherein said light emitting fiber comprises a hole transport layer disposed between said carbon nanotube fiber and said emissive layer.

3. The light emitting fiber of claim 2, wherein said light emitting fiber comprise a hole injection layer disposed between said nanotube fiber and said hole transport layer.

4. The light emitting fiber according to any one of claims 1-3, wherein said light emitting fiber comprises an electron transport layer disposed between said emissive layer and said conductive outer layer.

5. The light emitting fiber according to any one of claims 1-4, wherein said light emitting fiber comprises an electron injection layer disposed between said electron transport layer and said conductive outer layer.

6. The light emitting fiber of claim 1, wherein said light emitting fiber comprises a hole transport layer disposed between said emissive layer and said conductive outer layer.

7. The light emitting fiber of claim 6, wherein said light emitting fiber comprises a hole injection layer disposed between said hole transport layer and said conductive outer layer.

8. The light emitting fiber of claims 1 and 6-7, wherein said light emitting fiber comprises an electron transport layer disposed between said carbon nanotube fiber and said emissive layer.

9. The light emitting fiber of claim 8, wherein said light emitting fiber comprise an electron injection layer disposed between said carbon nanotube fiber and said electron transport layer.

10. The light emitting fiber according to any one of claims 1-9, wherein said carbon nanotube fiber comprise a single carbon nanotube fiber (CNTf).

11. The light emitting fiber according to any one of claims 1-9, wherein said carbon nanotube fiber comprise a plurality of carbon nanotube fibers.

12. The light emitting fiber according to any one of claims 1-11, wherein said carbon nanotube fibers are p-doped.

13. The light emitting fiber according to any one of claims 1-12, wherein said carbon nanotube fiber(s) range in diameter from about 1 μm, or from about 5 μm, or from about 10 μm, or from about 15 μm up to about 100 μm, or up to about 50 μm, or up to about 40 μm, or up to about 35 μm.

14. The light emitting fiber of claim 13, wherein said carbon nanotube fiber (s) range in diameter from about 15 μm up to about 35 μm.

15. The light emitting fiber according to any one of claims 1-14, wherein said carbon nanotube fiber(s) have a specific electrical conductivity at 20° C. higher than about 0.6×10⁴ S*cm²/g, or higher than about 2×10⁴ S*cm²/g, or higher than about 1.3×10⁵ S*cm²/g.

16. The light emitting fiber according to any one of claims 1-15, wherein said carbon nanotube fiber(s) have a current-carrying capacity of at least about 2000 A/cm, or at least about 10000 A/cm, or at least about 20000 A/cm, or at least about 30000 A/cm, a CNT fiber 25 μm in diameter.

17. The light emitting fiber according to any one of claims 1-16, wherein said nanotube fiber(s) have a modulus of at least about 120 GPa, or at least about 150 GPa, or at least about 200 GPa.

18. The light emitting fiber according to any one of claims 1-17, wherein said emissive layer comprises an inorganic nanoparticle layer, an inorganic thin film layer, an organic molecule emissive layer, or a polymeric emissive layer.

19. The light emitting fiber of claim 18, wherein said emissive layer comprises an inorganic nanoparticle layer and/or an inorganic thin film layer.

20. The light emitting fiber of claim 19, wherein said emissive layer comprises a metal halide perovskite.

21. The light emitting fiber of claim 20, wherein the metal halide perovskite comprises a material according to the formula CH₃NH₃MX, where M is Pb or SN, and X is one or two halides.

22. The light emitting fiber of claim 21, wherein said emissive layer comprises a lead halide perovskite.

23. The light emitting fiber of claim 22, wherein said emissive layer comprises a compound selected from the group consisting of CH₃NH₃PbBr₃, CH₃NH₃PbCl₃, CH₃NH₃PbI₃.

24. The light emitting fiber of claim 22, wherein said emissive layer comprises a CH₃NH₃PbBr₃.

25. The light emitting fiber of claim 21, wherein said emissive layer comprise a perovskite selected from the group consisting of CH₃NH₃PbI₃, CH₃NH₃,PbBr₃, CH₃NH₃PbCl₃, CH₃NH₃PbF₃, CH₃NH₃PbBrI₂, CH3NH3PbBrCl2, CH3NH3PbIBr2, CH₃NH₃PbICl₂, CH₃NH₃PbClBr₂, CH₃NH₃PbI₂Cl, CH₃NH₃SnI₃, CH₃NH₃SnBr₃, CH₃NH₃SnCl₃, CH₃NH₃ SnF₃, CH₃NH₃ SnBrI₂, CH₃NH₃ SnBrCl₂, CH₃NH₃ SnF₂Br, CH₃NH₃SnIBr₂, CH₃,NH₃SnICl₂, CH₃NH₃SnF₂I, CH₃NH₃SnClBr₂, CH₃NH₃SnI₂Cl, and CH₃NH₃SnF₂Cl.

26. The light emitting fiber according to any one of claims 22-25, wherein said emissive layer comprises perovskite nanocrystals/nanoparticles embedded in a polymer matrix.

27. The light emitting fiber of claim 26, wherein said wherein said polymer matrix comprises a polymer selected from the group consisting of PVP, and PEO.

28. The light emitting fiber of claim 19, wherein said inorganic nanoparticle layer or inorganic thin film layer comprises a material selected from the group consisting of Aluminium gallium arsenide (AlGaAs), Aluminium gallium indium nitride (AlGaInN), Aluminium gallium indium phosphide (AlGaInP), Aluminium gallium nitride (AlGaN), Aluminium gallium phosphide (AlGaP), Aluminium nitride (AlN), Boron nitride, Gallium arsenide (GaAs), Gallium arsenide phosphide (GaAsP), Gallium arsenide phosphide (GaAsP), Gallium arsenide phosphide (GaAsP), Gallium(III) nitride (GaN), Gallium(III) phosphide (GaP), Gallium(III) phosphide (GaP), Gallium(III) phosphide (GaP), Gallium(III) phosphide (GaP), Indium gallium nitride (InGaN), Indium gallium nitride (InGaN), Indium gallium nitride (InGaN), Indium gallium nitride (InGaN) (385-400 nm), and Zinc selenide (ZnSe).

29. The light emitting fiber of claim 18, wherein said emissive layer comprises an organic molecule emissive layer, and/or a polymeric emissive layer.

30. The light emitting fiber of claim wherein the emissive layer comprises a conjugated polymer.

31. The light emitting fiber of claim 30, wherein the emissive layer comprise a compound selected from the group consisting of Alq3 (tris(8-hydroxyquinolinato)aluminium), a polyphenylene or derivative thereof, a polyfluorenes or derivative thereof, a polythiophene or derivative thereof, polyfluoroene (PF), a polyphenylene vinylene (e.g., polyphenylene PPP) and derivatives thereif (e.g., poly[{2,5-di(3′,7′-dimethyloctyloxy)-1,4-phenylene-vinylene}-co-{3-(4′-(3″,7″-dimethyloctyloxy)phenyl)-1,4-phenylenevinylene}-co-{3-(3′-(3′,7′-dimethyloctyloxy)phenyl)-1,4-phenylenevinylene}] (aka. Super yellow or SY-PPV)), polyvinyl carbazole, and a polymers containing heteroaromatic rings.

32. The light emitting fiber of claim 30, wherein the emissive layer comprises a material selected from the group consisting of poly(p-phenylenevinylene) (PPV), polyphenylene (PPP), polyvinyl carbazole, Alq3, and super yellow.

33. The light emitting fiber of claim 30, wherein the emissive layer comprises a material selected from the group consisting of epidolidione, 1,1-bis(4-di-p-tolylaminophenyl)cyclohexane, [4,4′-bis[5,7-di(2-methyl-2-butyl)-2-benzoxazolyl]stilbene], [2,5-bis[5,7-di(2-methyl-2-butyl)-2-benzoxazolyl]thiophene], [2,2′-(1,4-phenylenedivinylene)bisbenzothiazole], [2,2′-(4,4′-biphenylene)bisbenzothiazole], [2,5-bis[5-(α,α-dimethylbenzyl)-2-benzoxazolyl]thiophene], [2,5-bis[5,7-di(2-methyl-2-butyl)-2-benzoxazolyl]-3,4-diphenyl-thiophene], and poly[2-methoxy-5-(2-ethylhexyloxy)-1,4-phenylenevinylene].

34. The light emitting fiber of claim 30, wherein the emissive layer comprises an Ir complex.

35. The light emitting fiber of claim 34, wherein the emissive layer comprises an Ir complex selected from the group consisting of to, ppy, tpy, zq, thp, dpo. C6, bo, bon, bt, op, αbsn, βbsn, tth, pq, and btp.

36. The light emitting fiber according to any one of claims 18-35, wherein said emissive layer ranges in thickness from about 10 nm, or from about 20 nm, or from about 30 nm, or from about 40 nm, or from about 50 nm up to about 500 nm, or up to about 400 nm, or up to about 300 nm, or up to about 200 nm, or up to about 100 nm, or up to about 500 nm, or up to about 1 μm, or up to about 5 μm, or up to about 10 μm, or up to about 20 μm, or up to about 30 μm, or up to about 40 μm, or up to about 50 μm.

37. The light emitting fiber according to any one of claims 2-36, wherein said hole transport layer, when present, comprises an organic molecule or polymer, or an inorganic nanoparticle or inorganic thin film.

38. The light emitting fiber of claim 37, wherein said hole transport layer comprises a layer or inorganic nanoparticles and/or an inorganic thin film.

39. The light emitting fiber of claim 38, wherein said inorganic nanoparticle and/or inorganic thin film comprises a materials selected from the group consisting of ZnO, TiO₂, CuI, and NiO.

40. The light emitting fiber of claim 37, wherein said hole transport layer comprises an organic molecule or polymer.

41. The light emitting fiber of claim 40, wherein said hole transport layer comprises a material selected from the group consisting of poly(3,4-ethylenedioxythiophene) polystyrene sulfonate (PDOT:PSS), poly(9-vinylcarbazole) (PVK), polybutadiene (PBD), poly(3-hexylthiophene), and 2,2′,7,7′-Tetrakis(N,N-di-p-methoxyphenylamine)-9,9′-spirobifluorene.

42. The light emitting fiber of claim 41, wherein said hole transport layer comprises poly(3,4-ethylenedioxythiophene) polystyrene sulfonate (PDOT:PSS).

43. The light emitting fiber of claim 40, wherein said hole transport layer comprises a material selected from the group consisting of a starburst triamine, a CFx fluorohydrocarbon polymer, a triarylamine or polythiophene polymer with conductivity dopants, an arylamine complexed a metal oxides, a p-type semiconducting organic complex, a triarylamine, a triaylamine on a spirofluorene core, an arylamine carbazole compound, a triarylamine with (di)benzothiophene/, (di)benzofuran, indolocarbazoles, an isoindole compound, and a metal carbene complex.

44. The light emitting fiber of claim 43, wherein said hole transport layer comprises a material shown in Table 2.

45. The light emitting fiber according to any one of claims 37-44, wherein said hole transport layer ranges in thickness from about 10 nm, or from about 20 nm, or from about 30 nm, or from about 40 nm, or from about 50 nm up to about 500 nm, or up to about 400 nm, or up to about 300 nm, or up to about 200 nm, or up to about 100 nm, or up to about 500 nm, or up to about 1 μm, or up to about 5 μm, or up to about 10 μm, or up to about 20 μm, or up to about 30 μm, or up to about 40 μm, or up to about 50 μm.

46. The light emitting fiber according to any one of claims 3-45, wherein said hole injection layer, when present, comprises a material shown in Table 3.

47. The light emitting fiber of claim 46, wherein said hole transport layer ranges in thickness from about 10 nm, or from about 20 nm, or from about 30 nm, or from about 40 nm, or from about 50 nm up to about 500 nm, or up to about 400 nm, or up to about 300 nm, or up to about 200 nm, or up to about 100 nm, or up to about 500 nm, or up to about 1 μm, or up to about 5 μm, or up to about 10 μm, or up to about 20 μm, or up to about 30 μm, or up to about 40 μm, or up to about 50 μm.

48. The light emitting fiber according to any one of claims 4-47, wherein said electron transport layer comprises an inorganic nanoparticle or inorganic thin film, or an organic molecule or polymer.

49. The light emitting fiber of claim 48, wherein said electron transport layer comprises a layer or inorganic nanoparticles and/or an inorganic thin film.

50. The light emitting fiber of claim 49, wherein said inorganic nanoparticle and/or inorganic thin film comprises a materials selected from the group Consisting of ZnO, TiO₂, CuI, and NiO.

51. The light emitting fiber of claim 50, wherein said inorganic nanoparticles and/or inorganic thin film comprises ZnO.

52. The light emitting fiber of claim 48, wherein said electron transport layer comprises a organic molecule or polymer.

53. The light emitting fiber according to any one of claims 48-52, wherein said electron transport layer ranges in thickness from about from about 10 nm, or from about 20 nm, or from about 30 nm, or from about 40 nm, or from about 50 nm up to about 500 nm, or up to about 400 nm, or up to about 300 nm, or up to about 200 nm, or up to about 100 nm, or up to about 500 nm, or up to about 1 μm, or up to about 5 μm, or up to about 10 μm, or up to about 20 μm, or up to about 30 μm, or up to about 40 μm, or up to about 50 μm.

54. The light emitting fiber according to any one of claims 5-53, wherein said electron injection layer comprises a material selected from the group consisting of (ZnO), 2-(2,4,6-Trimethoxyphenyl)-1,3-dimethyl-1H-benzoimidazol-3-ium (R3), (2-(2-methoxyphenyl)-1,3-dimethyl-1H-benzoimidazol-3-ium (o-MeO-DMBI or R1), LiF, and PETE.

55. The light emitting fiber of claim 54, wherein said electron injection layer, when present, ranges in thickness from about 10 nm, or from about 20 nm, or from about 30 nm, or from about 40 nm, or from about 50 nm up to about 500 nm, or up to about 400 nm, or up to about 300 nm, or up to about 200 nm, or up to about 100 nm, or up to about 500 nm, or up to about 1 μm, or up to about 5 μm, or up to about 10 μm, or up to about 20 μm, or up to about 30 μm, or up to about 40 μm, or up to about 50 μm.

56. The light emitting fiber according to any one of claim 1-55, wherein said conductive outer layer comprises a material selected from the group consisting of metallic or doped semiconducting nanoparticles, inorganic thin films, organic molecules and/or polymer layers.

57. The light emitting fiber of claim 56, wherein the conductive outer layer comprises a material selected from the group consisting of silver nanowires, gold nanowires, carbon nanotubes, graphene, indium zinc oxide (IZO, indium tin oxide (ITO), and PDOT:PSS.

58. The light emitting fiber of claim 56, wherein the conductive outer layer comprises silver.

59. The light emitting fiber according to any one of claims 56-58, wherein said electron transport layer ranges in thickness from about 10 nm, or from about 20 nm, or from about 30 nm, or from about 40 nm, or from about 50 nm up to about 500 nm, or up to about 400 nm, or up to about 300 nm, or up to about 200 nm, or up to about 100 nm, or up to about 500 nm, or up to about 1 μm, or up to about 5 μm, or up to about 10 μm, or up to about 20 μm, or up to about 30 μm, or up to about 40 μm, or up to about 50 μm.

60. The light emitting fiber according to any one of claims 1-59, wherein said emissive layer is substantially continuous along the length of said fiber.

61. The light emitting fiber according to any one of claims 1-59, wherein said emissive layer is disposed in one or more discrete locations along the length of said fiber.

62. The light emitting fiber according to any one of claims 1-61, wherein said emissive layer composition is substantially constant along the length of said fiber.

63. The light emitting fiber according to any one of claims 1-61, wherein said emissive layer composition varies in composition with location along the length of said fiber.

64. The light emitting fiber according to any one of claims 1-63, wherein said fiber is coated with an encapsulating material to reduce or prevent environmental degradation.

65. The light emitting fiber of claim 64, wherein said encapsulating material comprises a polymer.

66. The light emitting fiber of claim 65, wherein said encapsulating material comprises a material selected from the group consisting of (poly(methylmethacrylate) (PMMA), ethyl cellulose, polycarbonate and poly(4-methyl-1-pentene)), parylene, and epoxy.

67. The light emitting fiber according to any one of claims 1-66, where a plurality of said light emitting fibers are braided together to form a bundle.

68. The light emitting fiber according to any one of claims 1-66, where a plurality of said light emitting fibers are twisted together to form a bundle.

69. The light emitting fiber according to any one of claims 67-68, wherein said bundle comprises fibers that emit at different wavelengths.

70. The light emitting fiber according to any one of claims 1-69, wherein said light emitting fiber or a bundle of light emitting fibers is weavable.

71. The light emitting fiber of claim 70, wherein said light emitting fiber(s) are a component of a textile.

72. The light emitting fiber of claim 71, wherein said light emitting fiber is a component of a textile comprising other light emitting fibers.

73. The light emitting fiber according to any one of claims 71-72, wherein said light emitting fiber is a component of a textile comprising additional electronic components.

74. A method for producing light emission from a light emitting fiber, said method comprising:
providing a light emitting fiber according to any one of claims 1-73; and
applying a voltage between the carbon nanotube fiber(s) and the conductive layer sufficient to produce light emission from said light emitting fiber(s).

75. The method of claim 74, wherein said voltage ranges from about 0.1 V, or about 0.5 V, or about 1 V up to about 50 V, or up to about 40 V, or up to about 30 V, or up to about 20 V, or up to about 10 V, or up to about 9 V, or up to about 5 V.

76. An article of manufacture comprising a light emitting fiber according to any one of claims 1-73.

77. The article of manufacture of claim 76, wherein said article of manufacture comprises a textile.

78. The article of manufacture according to any one of claims 76-77, wherein said light emitting fiber provides a source of illumination.

79. The article of manufacture according to any one of claims 76-77, wherein said light emitting fiber provides component of a display that produces an image and/or an alphanumeric character.

80. A method of fabricating a light emitting fiber, said method comprising:
providing a carbon nanotube fiber;
coating said carbon nanotube fiber with an emissive layer to form a coated nanotube fiber structure; and
coating said structure with a layer that forms a conductive layer disposed outside said emissive layer.

81. The method of claim 80, wherein said method comprises coating said nanotube fiber with a hole transport layer disposed before coating said nanotube fiber with said emissive layer.

82. The method of claim 81, wherein said method comprises coating said nanotube fiber with a hole injection layer before coating said nanotube fiber with said hole transport layer.

83. The method according to any one of claims 80-82, wherein said method comprises coating said nanotube fiber structure with an electron transport layer before coating said structure with the layer that forms a conductive layer.

84. The method according to any one of claims 80-83, wherein said providing a carbon nanotube fiber comprises using wet-spinning to produce said carbon nanotube fiber.

85. The method of claim 84, wherein said wet spinning comprises:
supplying a spin-dope comprising carbon nanotubes (CNT) to a spinneret;
extruding the spin-dope through at least one spinning hole in the spinneret to form spun CNT fiber(s); and
coagulating the spun CNT fiber(s) in a coagulation medium (a non-solvent) to form a solid CNT fiber.

86. The method of claim 85, wherein said spin-dope comprises a carbon nanotubes in a super acid solution.

87. The method of claim 86, wherein said super acid solution comprises chlorosulfonic acid.

88. The method according to any one of claims 80-87, wherein said carbon nanotube fiber is doped.

89. The method according to any one of claims 80-88, wherein the coating steps is through a roll-to-roll liquid-phase processing technique.

90. The method of claim 89, wherein said roll-to-roll processing techniques comprises holding the fiber under tension using at least two winding drums rotating at the same speed but in different directions and passing the fiber through a solution of the desired material to be coated.

91. The method of claim 90, wherein extra drums provided to guide the fiber and ensure an appropriate receding angle at the coating stage.

92. The method according to any one of claims 90-91, wherein a motorized roller is used to determine the speed at which the fiber moves through the solution is controlled to tune the coating thickness achieved.

93. The method according to any one of claims 80-92, wherein the thickness of each of the coatings varies between tens to thousands or between tens to hundreds of nanometers.

94. The method according to any one of claims 90-93, wherein a single coating pass is used for each layer.

95. The method according to any one of claims 90-93, wherein multiple passes are used for one or more layers.

96. The method according to any one of claims 80-95, where a furnace is used to anneal a coating at the appropriate temperature as needed.

97. The method according to any one of claims 80-96, wherein the entire coating process takes place in an inert environment.

98. The method according to any one of claims 80-96, wherein the entire coating process takes place in air.

99. The method of claim 98, wherein said inert environment comprises nitrogen or argon.

100. The method according to any one of claims 80-99, wherein said method produces a light emitting fiber according to any one of claims 1-66.
